(19) United States
(12) Patent Application Publication
(10) Pub. No.: US 2026/0122988 A1
(43) Pub. Date: Apr. 30, 2026

(54) STAGGERED HORIZONTALLY ORIENTED AND VERTICALLY ORIENTED NANOSHEET GATES

(71) Applicant: INTERNATIONAL BUSINESS MACHINES CORPORATION, ARMONK, NY (US)

(72) Inventors: HUIMEI ZHOU, Albany, NY (US); Chen Zhang, Santa Clara, CA (US); Ruilong Xie, Niskayuna, NY (US); Shahrukh Khan, Sandy Hook, CT (US)

(21) Appl. No.: 18/929,505

(22) Filed: Oct. 28, 2024

(51) Int. Cl. H01L 29/06; H01L 21/8234; H01L 23/528; H01L 27/088; H01L 29/08; H01L 29/423; H01L 29/66; H01L 29/775; H01L 29/78; H01L 29/786

(52) U.S. Cl. CPC H10D 62/121; H10D 30/014; H10D 30/43; H10D 30/6735; H10D 30/6757; H10D 30/797; H10D 62/151; H10D 64/017; H10D 84/013; H10D 84/038; H10D 84/83; H10W 20/427

(57) ABSTRACT

A semiconductor device includes a top transistor stacked over a bottom transistor. The top transistor comprises horizontally oriented nanosheet gates, and the bottom transistor comprises vertically oriented nanosheet gates. The top transistor and the bottom transistor are staggered.

### BACKGROUND

### Technical Field

The present disclosure generally relates to semiconductors, and more particularly, to semiconductors with staggered horizontally oriented and vertically oriented nanosheet gate structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a top transistor stacked over a bottom transistor. The top transistor comprises horizontally oriented nanosheet gates, and the bottom transistor comprises vertically oriented nanosheet gates.

In one embodiment, each of the top transistor and the bottom transistor further comprises staggered source/drain regions.

In one embodiment, the staggered source/drain regions are separated by an insulator.

In one embodiment, the horizontally oriented nanosheets and the vertically oriented nanosheet gates are isolated by an interlayer dielectric.

In one embodiment, the semiconductor device includes an insulator over source/drain regions of the bottom transistor.

In one embodiment, the vertically oriented nanosheet gates are encapsulated by an insulator.

In one embodiment, the horizontally oriented nanosheet gates are separated by an insulator.

In one embodiment, the horizontally oriented nanosheet gates and the vertically oriented nanosheet gates include silicon.

According to an embodiment, a method for fabrication of a semiconductor device includes forming a top transistor comprising horizontally oriented nanosheet gates, forming a bottom transistor comprising vertically oriented nanosheet gates, stacking the top transistor over the bottom transistor.

In one embodiment, the method includes forming staggered source/drain regions in each of the top transistor and the bottom transistors.

In one embodiment, the method includes isolating the staggered source/drain regions by an insulator.

In one embodiment, the method includes isolating the horizontally oriented nanosheets and the vertically oriented nanosheet gates by an interlayer dielectric.

In one embodiment, the method includes forming an insulator over source/drain regions of the bottom transistor.

In one embodiment, the method includes encapsulating the vertically oriented nanosheet gates by an insulator.

In one embodiment, the method includes isolating the horizontally oriented nanosheet gates by an insulator.

In one embodiment, the horizontally oriented nanosheet gates and the vertically oriented nanosheet gates include silicon.

According to an embodiment, a semiconductor device includes a top transistor stacked over a bottom transistor. Each of the top transistor and the bottom transistor further comprises staggered source/drain regions.

In an embodiment, the top transistor comprises horizontally oriented nanosheet gates, and the bottom transistor comprises vertically oriented nanosheet gates.

In one embodiment, the staggered source/drain regions are separated by an insulator.

In one embodiment, the horizontally oriented nanosheets and the vertically oriented nanosheet gates are isolated by an interlayer dielectric.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A-1C illustrates a semiconductor device, according to an embodiment.

FIG. 1D illustrates a top view of the semiconductor device.

FIG. 2 illustrates a semiconductor device after the preparation of the substrate, in accordance with some embodiments.

FIG. 3 illustrates a semiconductor device after the formation of the active region, in accordance with some embodiments.

FIG. 4 illustrates a semiconductor device after the patterning of the active regions, in accordance with some embodiments.

FIG. 5 illustrates a semiconductor device after the formation of a liner layer, in accordance with some embodiments.

FIG. 6 illustrates a semiconductor device after the removal of portions of the second SiGe, in accordance with some embodiments.

FIG. 7 illustrates a semiconductor device after the formation of a SiGe layer, in accordance with some embodiments.

FIG. 8 illustrates a semiconductor device after the formation of silicon, in accordance with some embodiments.

FIG. 9 illustrates a semiconductor device after the removal of portions of the silicon layer, in accordance with some embodiments.

FIG. 10 illustrates a semiconductor device after the formation of SiGe layer, in accordance with some embodiments.

FIG. 11 illustrates a semiconductor device after the partial removal of the liner, in accordance with some embodiments.

FIGS. 12A-12B illustrate a semiconductor device after the formation of dummy gates, in accordance with some embodiments.

FIGS. 13A-13B illustrate a semiconductor device after the patterning of the gate regions, in accordance with some embodiments.

FIGS. 14A-14E illustrate a semiconductor device after the formation of a spacer, in accordance with some embodiments.

FIGS. 15A-15E illustrate a semiconductor device after the etching, in accordance with some embodiments.

FIGS. 16A-16E illustrate a semiconductor device after the removal of the high-SiGe, in accordance with some embodiments.

FIGS. 17A-17E illustrate a semiconductor device after the forming the silicon oxide, in accordance with some embodiments.

FIGS. 18A-18E illustrate a semiconductor device after the removal of SiGe, in accordance with some embodiments.

FIGS. 19A-19E illustrate a semiconductor device after the formation of middle dielectric isolation, in accordance with some embodiments.

FIGS. 20A-20E illustrate a semiconductor device after the formation of liner, in accordance with some embodiments.

FIGS. 21A-21E illustrate a semiconductor device after the patterning of the silicon oxide, in accordance with some embodiments.

FIGS. 22A-22E illustrate a semiconductor device after the removal of a lower portion of the stacks, in accordance with some embodiments.

FIGS. 23A-23E illustrate a semiconductor device after the removal of a SiGe, in accordance with some embodiments.

FIGS. 24A-24E illustrate a semiconductor device after the formation of an insulation layer, in accordance with some embodiments.

FIGS. 25A-25E illustrate a semiconductor device after the formation of an oxide layer, in accordance with some embodiments.

FIGS. 26A-26E illustrate a semiconductor device after the formation of placeholders and bottom source/drain regions, in accordance with some embodiments.

FIGS. 27A-27E illustrate a semiconductor device after the formation of silicon oxide, in accordance with some embodiments.

FIGS. 28A-28E illustrate a semiconductor device after the removal of the liner, in accordance with some embodiments.

FIGS. 29A-29E illustrate a semiconductor device after the indentation of the insulation layer, in accordance with some embodiments.

FIGS. 30A-30E illustrate a semiconductor device after the formation of the insulation layer, in accordance with some embodiments.

FIGS. 31A-31E illustrate a semiconductor device after the formation of top source/drain regions, in accordance with some embodiments.

FIGS. 32A-32E illustrate a semiconductor device after the formation of interlayer dielectric, in accordance with some embodiments.

FIGS. 33A-33E illustrate a semiconductor device after the removal of the dummy gates, in accordance with some embodiments.

FIGS. 34A-34E illustrate a semiconductor device after the removal of the SiGe in the channel region, in accordance with some embodiments.

FIGS. 35A-35E illustrate a semiconductor device after forming high-k and work function metal, in accordance with some embodiments.

FIGS. 36A-36E illustrate a semiconductor device after gate cut, in accordance with some embodiments.

FIGS. 37A-37E illustrate a semiconductor device after the filling of gate cut regions, in accordance with some embodiments.

FIGS. 38A-38E illustrate a semiconductor device after the formation of contacts, in accordance with some embodiments.

FIGS. 39A-39E illustrate a semiconductor device after back end of line build and wafer bonding, in accordance with some embodiments.

FIGS. 40A-40E illustrate a semiconductor device after the partial removal of the Substrate, in accordance with some embodiments.

FIGS. 41A-41E illustrate a semiconductor device after the removal of the SiGe, in accordance with some embodiments.

FIGS. 42A-42E illustrate a semiconductor device after the formation of the SiO2, in accordance with some embodiments.

FIGS. 43A-43E illustrate a semiconductor device after the removal of the substrate, in accordance with some embodiments.

FIGS. 44A-44E illustrate a semiconductor device after the formation of SiO2, in accordance with some embodiments.

FIGS. 45A-45E illustrate a semiconductor device after the patterning of the backside contact, in accordance with some embodiments.

FIGS. 46A-46E illustrate a semiconductor device after the removal of the placeholder, in accordance with some embodiments.

FIGS. 47A-47E illustrate a semiconductor device after the formation of the backside contact, in accordance with some embodiments.

FIGS. 48A-48E illustrate a semiconductor device after the formation of the backside power delivery network, in accordance with some embodiments.

FIG. 49 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

The current approach to stacked field-effect transistors (FETs), as well as methods described in published prior art, typically involves a shared gate that extends from the top to the bottom FETs within the stack. In this configuration, multiple transistors are vertically stacked on top of each other, and a single gate electrode controls all the transistors simultaneously. The shared gate serves as the control terminal for the entire stack, modulating the flow of charge carriers (electrons or holes) in the channels of all the transistors. This means that the gate voltage applied influences the operation of every transistor in the stack uniformly.

While this shared gate approach simplifies the fabrication process by reducing the number of gate electrodes that need to be formed, it also imposes limitations. One drawback is the lack of individual control over each transistor in the stack. Since all the transistors share the same gate, they all switch on and off together, which can be restrictive in circuit applications that require independent control of transistors for complex logic functions or power management.

A staggered stacked FET is proposed as a very attractive device option for stacked nanosheet (NS) architectures. In this design, the transistors are stacked vertically but are laterally offset or staggered relative to each other. This means that the source, drain, and gate regions of the transistors do not align perfectly in the vertical direction. The staggered configuration provides more accessible areas on each transistor layer for forming electrical contacts, making it much easier to connect the transistors to other components in the circuit.

Forming dependable contacts is crucial for the performance of semiconductor devices. Contacts are the interfaces through which electrical signals enter and exit the transistors, connecting them to the rest of the electronic system. In traditional vertically stacked FETs with shared gates, accessing individual transistor layers for contact formation can be challenging due to the alignment and limited space. The staggered arrangement alleviates this issue by exposing parts of each transistor layer, allowing for straightforward contact formation.

Additionally, the staggered stacked FET offers better scalability compared to the shared gate approach. Scalability refers to the ability to reduce the physical dimensions of the device while maintaining or improving performance. As the semiconductor industry pushes towards smaller and more densely packed devices, scalability becomes a critical factor. The staggered design allows for individual optimization of each transistor layer and facilitates the integration of more transistors within the same chip area, enhancing the computational power and efficiency of the device.

Disclosed is a semiconductor device with vertical and horizontal stacked gate-all-around (GAA) nanosheet (NS) transistors with separate gates. In the disclosed design, transistors are stacked both vertically and horizontally, enhancing the utilization of the available space on the chip. The nanosheet refers to the ultra-thin semiconductor channels used in these transistors. Nanosheets are flat, ribbon-like structures that offer excellent control over the flow of charge carriers, which is essential for the performance of advanced transistors.

The gate-all-around (GAA) configuration is a transistor architecture where the gate material completely surrounds the nanosheet channel on all sides-top, bottom, and sidewalls. This full enclosure provides superior electrostatic control over the channel compared to other transistor designs such as FinFETs or planar FETs. Enhanced control reduces leakage currents and mitigates short-channel effects, which are detrimental to transistor operation at nanoscale dimensions.

By using separate gates for each transistor in the stack, the disclosed semiconductor device allows for individual control over the operation of each transistor. Unlike the shared gate approach, this design enables different gate voltages to be applied to different transistors within the stack. Such an independent control is highly beneficial for complex logic circuits and power management applications, where transistors need to switch at different times or operate under different conditions.

The combination of vertical and horizontal stacking with separate gates in a GAA nanosheet architecture represents an advancement in transistor design, as it addresses the limitations of the shared gate approach by improving contact formation and scalability while enhancing device performance through superior electrostatic control and individual transistor operation. The structure paves the way for more efficient, powerful, and compact semiconductor devices that meet the demands of modern electronic applications.

Accordingly, the teachings herein provide methods and systems of staggered horizontally oriented and vertically oriented nanosheet gates. The techniques described herein may be implemented in a number of ways. Example implementations are provided below with reference to the following figures.

Example Semiconductor Device with Semiconductors with Staggered Horizontally Oriented and Vertically Oriented Nanosheet Gate Structure

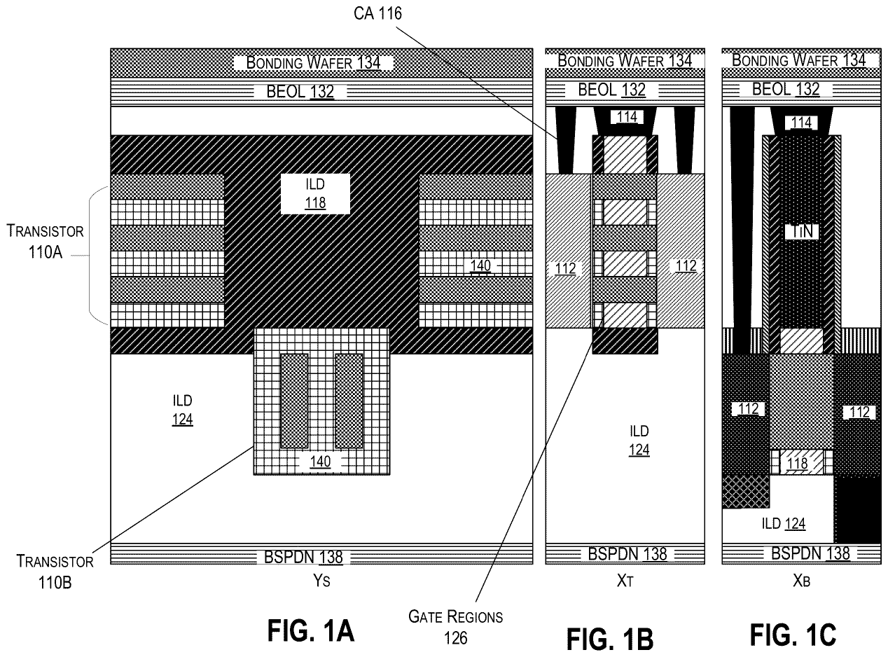

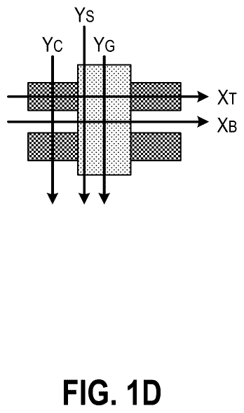

Reference now is made to FIGS. 1A-1C, which are simplified cross-section views of a semiconductor device, consistent with an illustrative embodiment. FIG. 1D illustrates a top view of the semiconductor device. The semiconductor device includes a top transistor 110A, and a bottom transistor 110B. Each of the top transistor 110A and the bottom transistor 110B includes source/drain regions 112, gate contacts 114, contacts, CA 116, an insulation layer 140, interlayer dielectrics, ILD 118 and ILD 124, gate regions 126, a back end of line, BEOL 132, a bonding wafer 134, and a backside power delivery network, BSPDN 138.

Generally, the source/drain regions are salient components that play relevant roles in the semiconductor device's operation. In various embodiments, the source/drain regions 112 are region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The source/drain regions 112 of the top transistor 110A and the bottom transistor 110B can be arranged in a staggered configuration. In more details, in the semiconductor device, the source region (where charge carriers enter the transistor) and the drain region (where charge carriers exit the transistor) of the top transistor 110A are not perfectly aligned with those of the bottom transistor 110B. Instead, the source/drain regions 112 are offset, e.g., staggered, relative to each other, which means that the source region of the top transistor 110A is not directly positioned above the drain region of the bottom transistor 110B.

By offsetting the source and drain regions, the transistors can be isolated electrically. The insulating material between the staggered regions can prevent unwanted current leakage and reduces parasitic capacitance, which can degrade the performance of the device. The isolation enhances the independence of each transistor's operation, allowing them to function more efficiently without interfering with each other. Additionally, staggering the source and drain regions can facilitate contact formation. In densely packed semiconductor devices, accessing the source and drain regions for electrical connections can be challenging if they are aligned vertically. The staggered configuration of the semiconductor device can provide more surface area and space for forming contacts and interconnects, simplifying the manufacturing process and improving the scalability of the device.

By arranging the source and drain regions in a staggered manner, the semiconductor device can further benefit from improved thermal management. The separation between the active regions allows for enhanced heat dissipation, reducing thermal interference between the transistors. This contributes to the overall reliability and longevity of the semiconductor device by preventing overheating and ensuring stable operation under various conditions.

The CA 116, located over the source/drain regions 112, can establish connections between the source/drain regions 112 and BEOL 132. The CA 116 can ensure efficient electrical routing and connectivity within the semiconductor device. The fabrication of the CA 116 can involve lithography and etching processes to define the contact area. The CA 116 can be made using conductive materials such as copper (Cu) or tungsten (W).

In various embodiments, the gate regions 126 serve as control elements that regulate the flow of current through the semiconductor device. The gate regions 126 can be composed of a conductive material. The gate regions 126 can control the flow of electric current between the source and drain regions. In addition to acting as a switch, modulating the gate voltage can enable the gate regions 126 to control the current flowing through the channel region, resulting in amplified output signals.

In an embodiment, the gate regions 126 can enable the implementation of Boolean logic operations, such as AND, OR, and NOT, by controlling the flow of current based on the input voltages. In some embodiments, the gate regions 126, along with other active device components, can facilitate the miniaturization and integration of electronic circuits. The ability to control the channel region's conductivity through the gate voltage allows for compact and highly efficient circuit designs.

In some embodiments, the horizontally oriented nanosheets and the vertically oriented nanosheet gates are isolated by the ILD 118 and 124. The horizontally oriented nanosheets can be ultra-thin semiconductor layers that serve as the channels through which charge carriers (electrons or holes) move when the transistor is operating. The vertically oriented nanosheet gates can be gate electrodes that control the flow of charge carriers in these channels by applying an electric field. The ILD 118 and ILD 124 are insulating materials placed between the horizontally oriented nanosheets and the vertically oriented nanosheet gates to provide electrical isolation between these components, preventing unintended electrical interactions. ILD 118 and ILD 124 ensure that the gate electrodes can effectively control the channel regions without interference from other layers, maintaining the integrity of the transistor's operation and allowing for precise modulation of current flow.

The semiconductor device can include the insulator layer 140 over the source and drain regions of the bottom transistor 110B. The insulator layer 140 covers the source and drain regions of the bottom transistor 110B in a stacked configuration. By placing the insulating material over these regions, the device prevents electrical interference from components located above the bottom transistor. The insulator layer 140 can act as a protective barrier, shielding the source and drain from potential contaminants or charges that could alter their behavior, and ensure that the bottom transistor 110B operates correctly without being affected by the electrical activity of transistors or interconnects positioned above it, thus enhancing the device's reliability and performance.

In some embodiments, the vertically oriented nanosheet gates can be encapsulated by the insulator layer 140. Encapsulation involves surrounding the gate electrode completely with an insulating material. In such embodiments, the insulator layer 140 can serve to electrically isolate the gate from other parts of the device, preventing unintended coupling or interference from adjacent structures or layers. By encapsulating the vertically oriented nanosheet gates, the gate's electric field is confined to influence only its intended nanosheet channel. The isolation improves the transistor's switching characteristics, reduce leakage currents, and prevent external electric fields from affecting the gate's control over the channel. Encapsulation further protects the gate material from environmental factors such as moisture or contaminants that could degrade its performance over time.

In some embodiments, the horizontally oriented nanosheet gates can be separated by the insulator layer 140. In some embodiments, the gate electrodes that are aligned horizontally across the device are spaced apart with insulating material between them. The insulator layer 140 can ensure that each gate operates independently by preventing electrical interaction between adjacent gates. Such a separation reduces parasitic capacitance and crosstalk, which can slow down signal propagation and degrade the performance of high-speed circuits. By isolating the horizontally oriented nanosheet gates with the insulator layer 140, the device maintains high signal integrity and allows for precise control of each individual transistor within the integrated circuit.

The nanosheets, NS, can include thin layers of conductive material positioned between the doped regions and the corresponding gate regions. The NS can enhance control over the channel region of the semiconductor device. By using the NS, the semiconductor device can achieve greater control over the switching characteristics of the semiconductor device, improving its speed, power efficiency, and scaling potential.

The NS can feature alternating layers that extend horizontally between the doped regions and the gate regions. The horizontal layers provide a pathway for current while minimizing the overall footprint of the device, allowing for denser integration in advanced semiconductor designs. The alternating layers typically include materials such as silicon, which is favored for its excellent electrical properties and compatibility with conventional semiconductor manufacturing techniques. Silicon's ability to form high-quality junctions with both N-type and P-type materials makes it ideal for use in nano-sheet gate structures, enabling the device to achieve optimal performance across a wide range of applications. The combination of advanced doping techniques, isolation methods, and nano-sheet gate technology, allows the semiconductor device to deliver highly controlled, efficient current flow. Such a combination is particularly well-suited for applications in power amplification, signal switching, and integrated circuits where performance, scaling, and reliability are essential, while it will be understood that the teachings herein can be used in many other applications as well.

Example Fabrication of Semiconductor Device with Nanosheet Gate

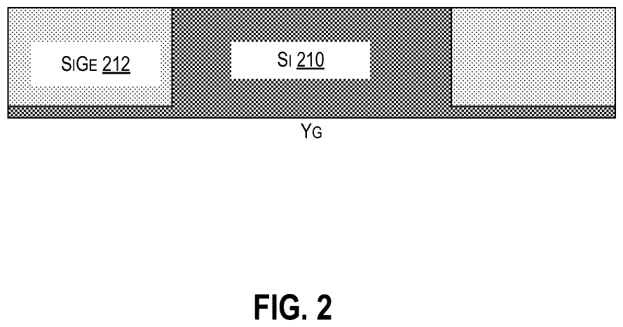

With the foregoing description of an example semiconductor device, it may be helpful to discuss an example process of manufacturing the same. To that end, FIGS. 2-49 illustrate various acts in the manufacture of a semiconductor device, consistent with illustrative embodiments.

Reference now is made to FIG. 2, which is a simplified cross-section view of a semiconductor device, after the preparation of the substrate, consistent with an illustrative embodiment. The semiconductor device can include a substrate 210 and a layer of SiGe 212.

In the illustrative example depicted in FIG. 2, the semiconductor device is depicted as being on silicon as the substrate 210, while it will be understood that other types as the substrate 210 may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 210 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

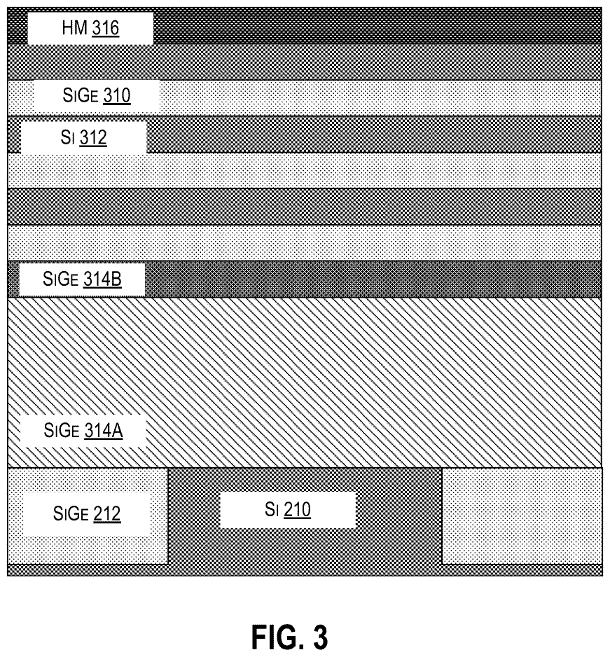

FIG. 3 illustrates a semiconductor device after the formation of the active region, in accordance with some embodiments. In some embodiments, the alternating layers of SiGe 310 and Si 312 are formed over the substrate 210. Two layers of SiGe with high concentration of Ge, e.g., about 40˜50% and 23˜30%, are formed directly over the substrate 210. A hard mask, HM 316, is formed over the semiconductor device.

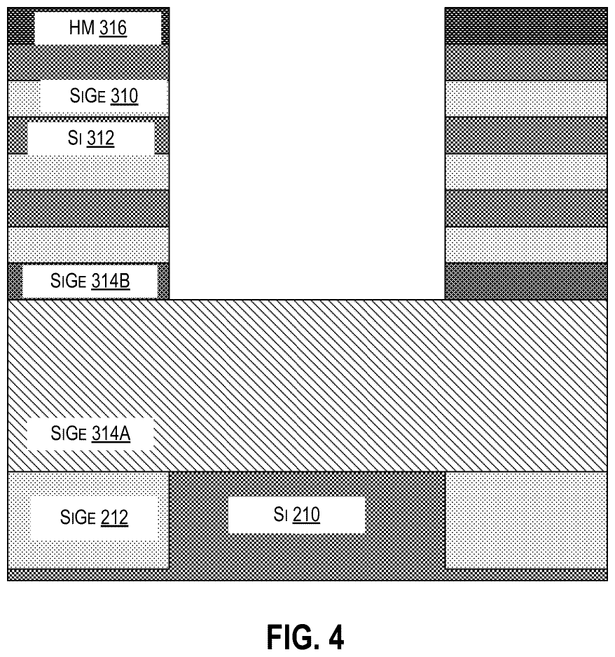

FIG. 4 illustrates a semiconductor device after the patterning of the active regions, in accordance with some embodiments. In some embodiments, portions of the HM 316, the alternating layers of SiGe 310 and Si 312, and one of the two layers of SiGe are removed to expose one of the layers of the SiGe with high concentration of Ge.

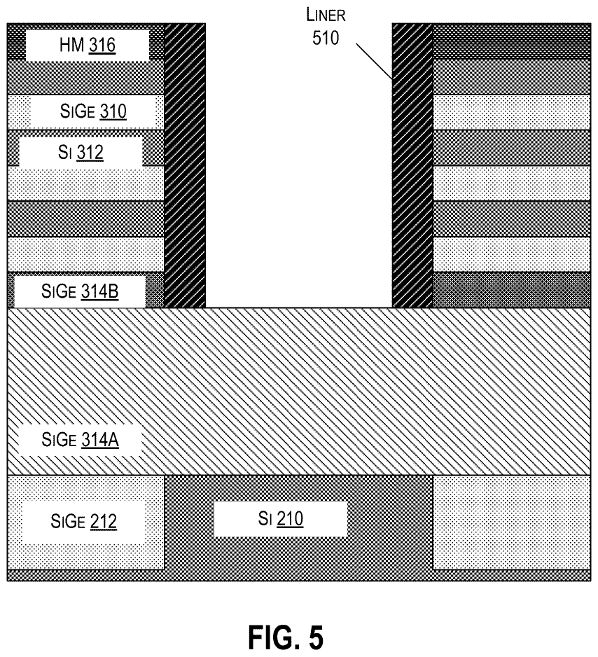

FIG. 5 illustrates a semiconductor device after the formation of a liner layer, in accordance with some embodiments. In some embodiments, a liner 510 is formed over sidewalls of the patterned section of the semiconductor device.

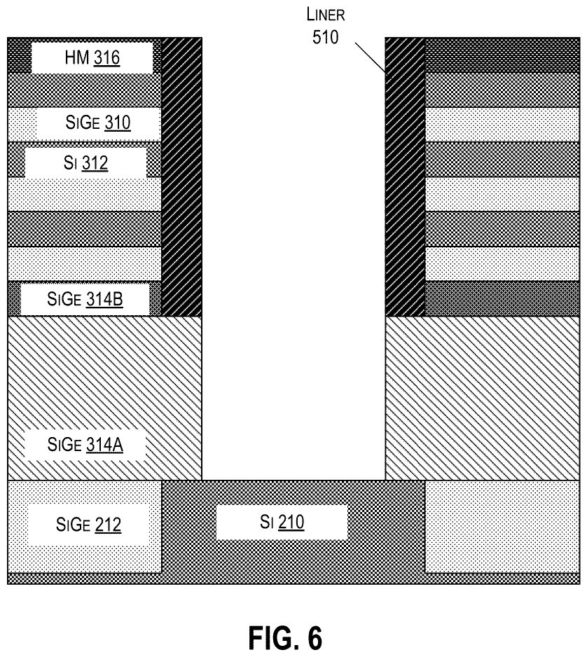

FIG. 6 illustrates a semiconductor device after the removal of portions of the second SiGe, in accordance with some embodiments. In some embodiments, exposed portions of the SiGe are removed to expose the upper surface of the substrate 210.

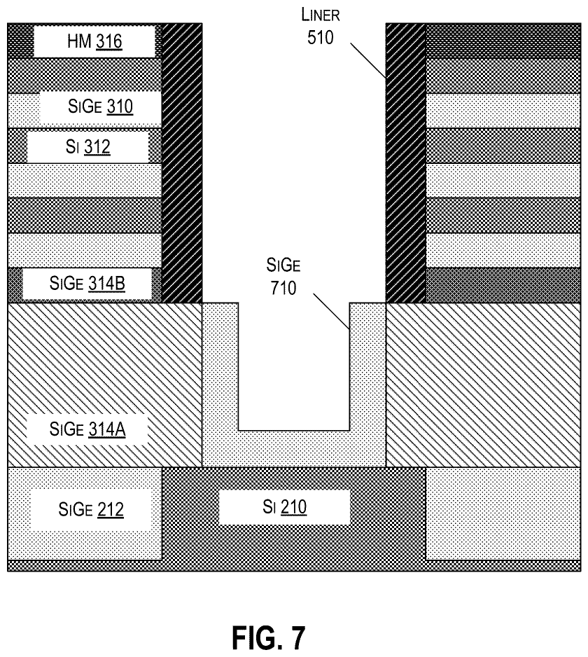

FIG. 7 illustrates a semiconductor device after the formation of a SiGe layer, in accordance with some embodiments. In some embodiments, a layer of SiGe 710 is formed over the exposed portions of the substrate 210 and the sidewalls of the SiGe.

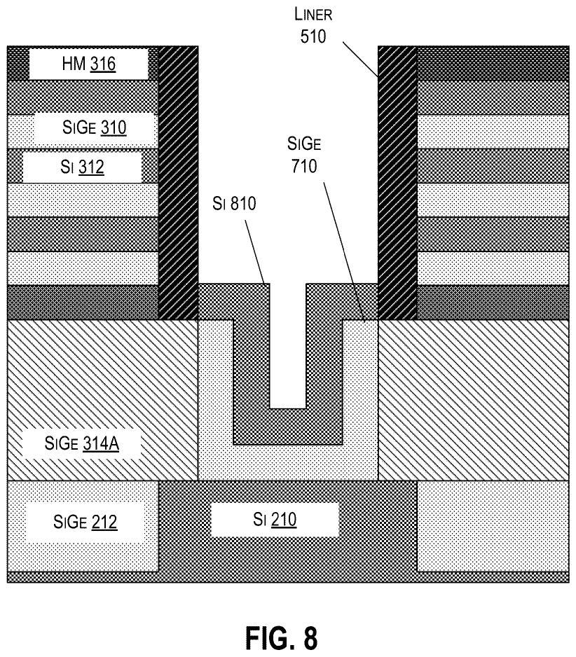

FIG. 8 illustrates a semiconductor device after the formation of silicon, in accordance with some embodiments. In some embodiments, silicon layer, Si 810, is formed over the SiGe 710.

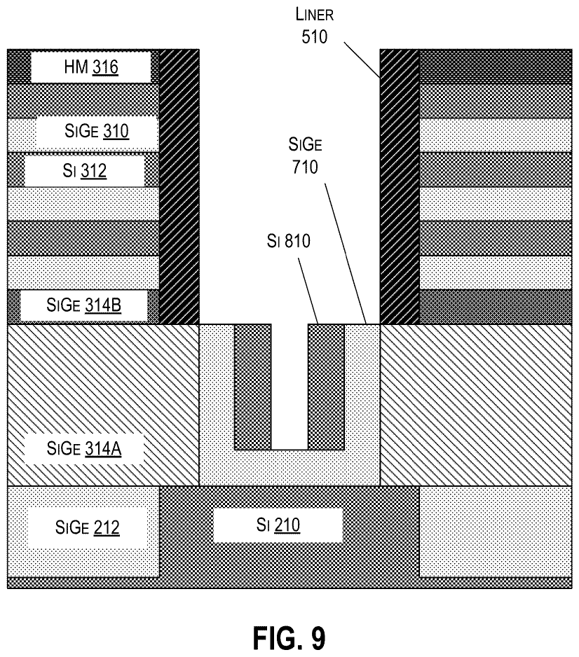

FIG. 9 illustrates a semiconductor device after the removal of portions of the silicon layer, in accordance with some embodiments. In some embodiments, portions of the Si 810 are removed.

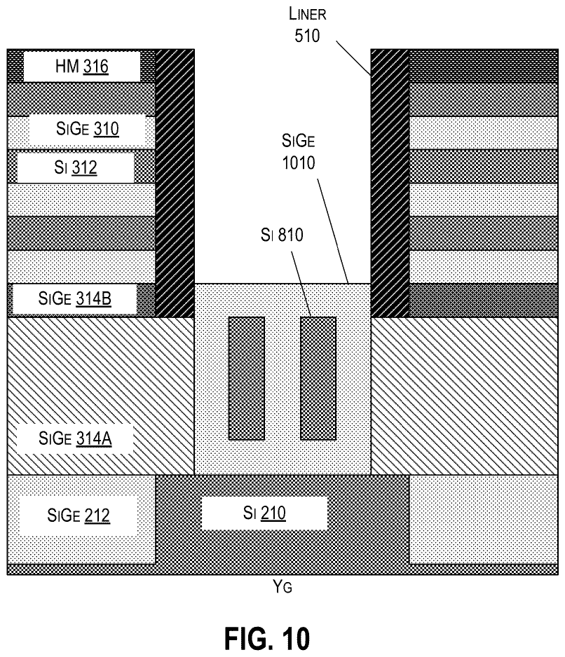

FIG. 10 illustrates a semiconductor device after the formation of SiGe layer, in accordance with some embodiments. In some embodiments, a layer of SiGe 1010 is formed to encapsulate the Si 810.

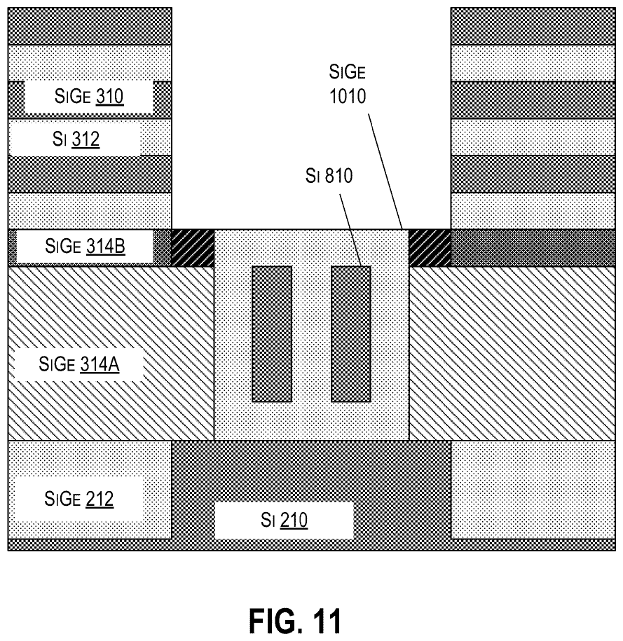

FIG. 11 illustrates a semiconductor device after the partial removal of the liner, in accordance with some embodiments. In some embodiments, portions of the liner are removed to expose the sidewalls of the alternating layers of SiGe 310 and Si 312.

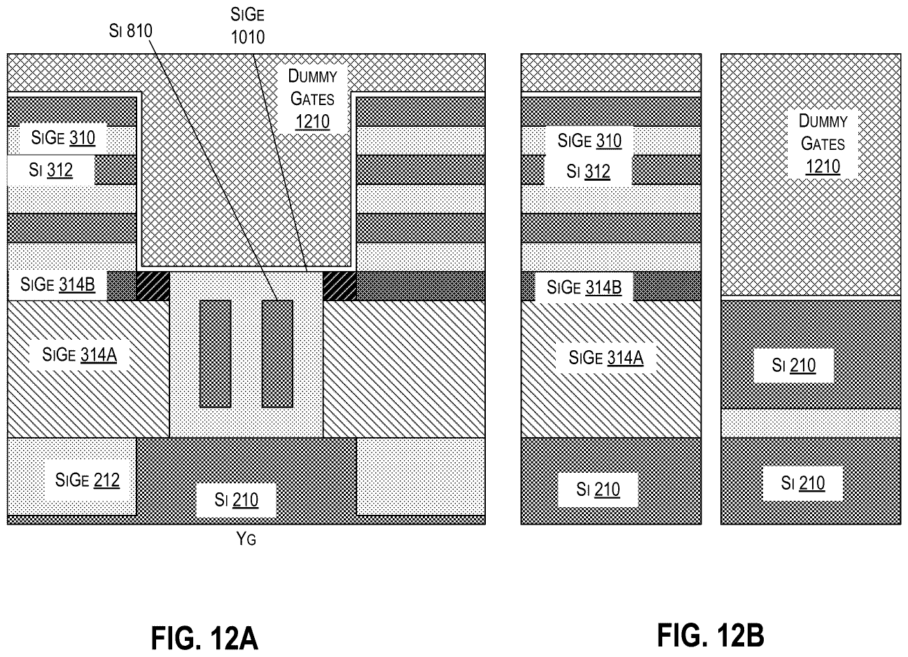

FIGS. 12A-12B illustrate a semiconductor device after the formation of dummy gates, in accordance with some embodiments. In some embodiments, a dummy oxide 1210 is formed over the semiconductor device, followed by the formation of dummy gates 1212.

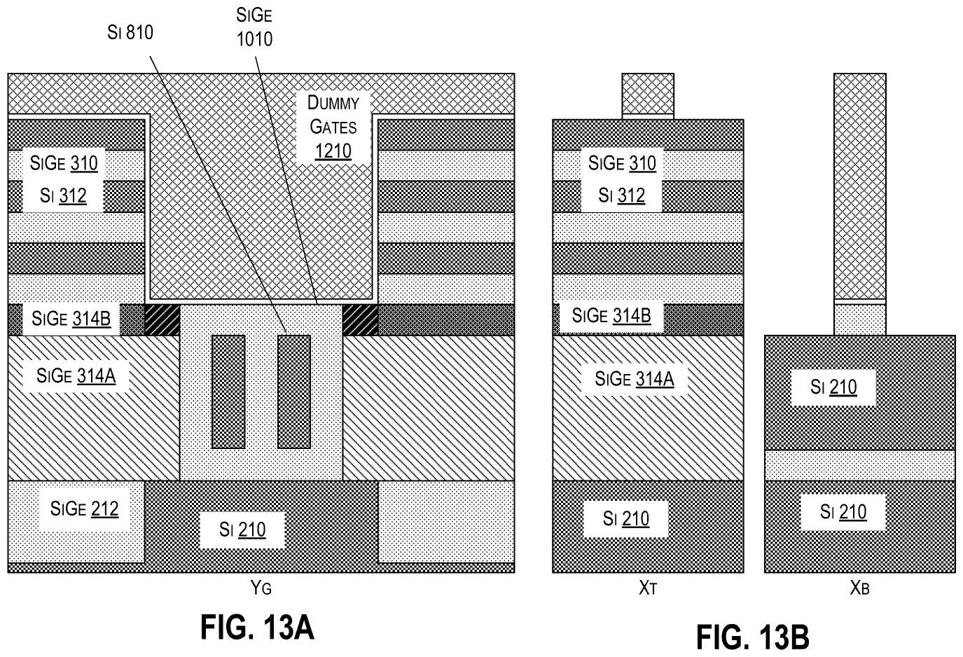

FIGS. 13A-13B illustrate a semiconductor device after the patterning of the gate regions, in accordance with some embodiments. In some embodiments, portions of the dummy gates 1212 are removed.

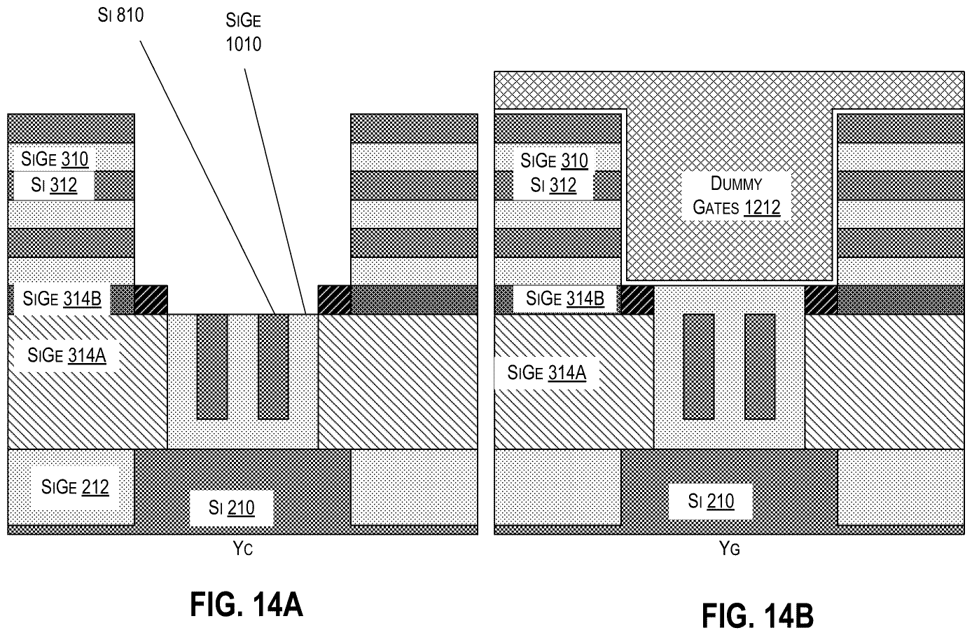

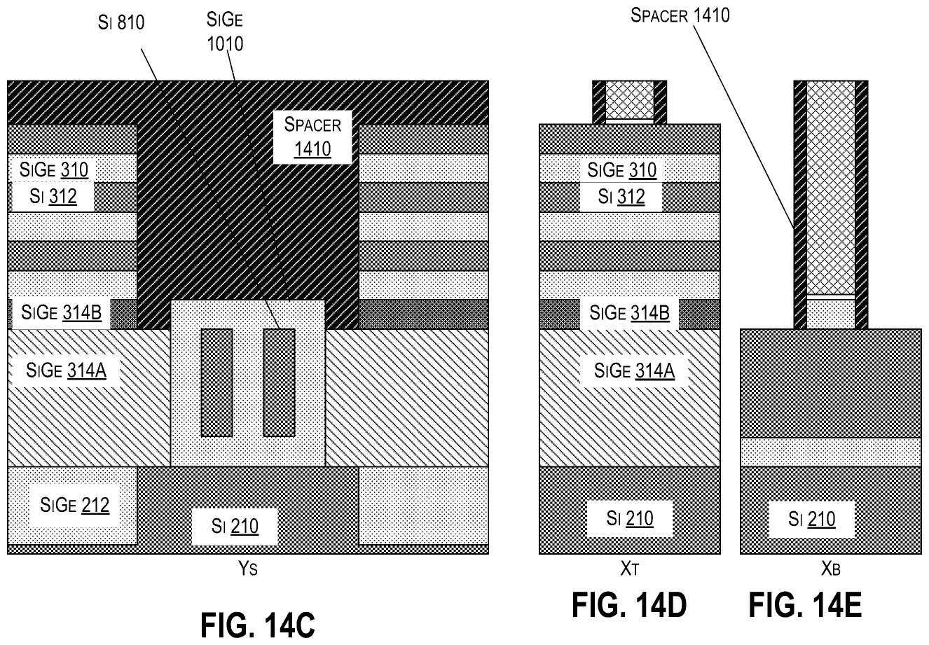

FIGS. 14A-14E illustrate a semiconductor device after the formation of an insulator, in accordance with some embodiments. In some embodiments, an insulator 1410 is formed over the semiconductor device.

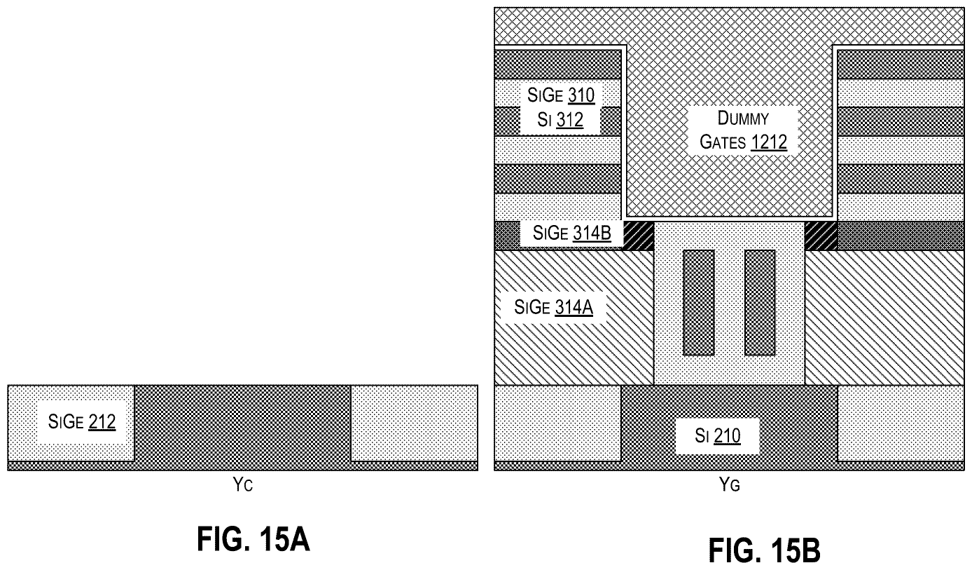

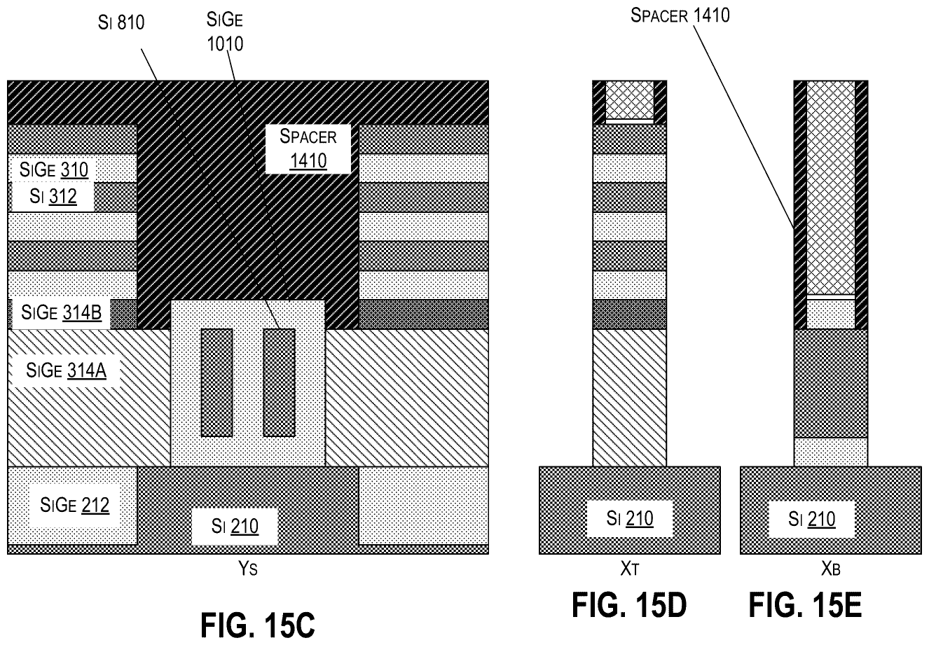

FIGS. 15A-15E illustrates a semiconductor device after the patterning of the semiconductor device, in accordance with some embodiments. In some embodiments, portions of the stacks over the substrate 210 are thinned by an etching process.

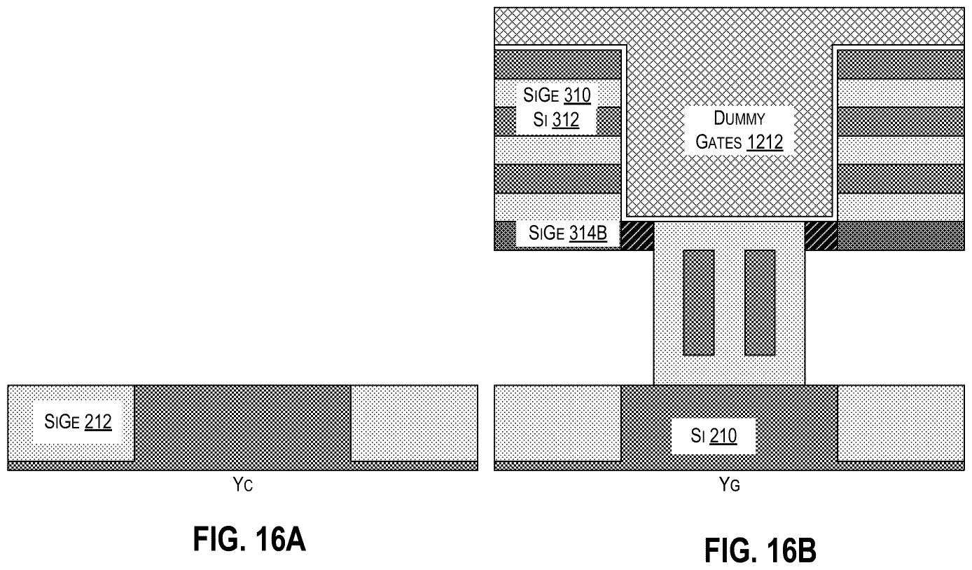

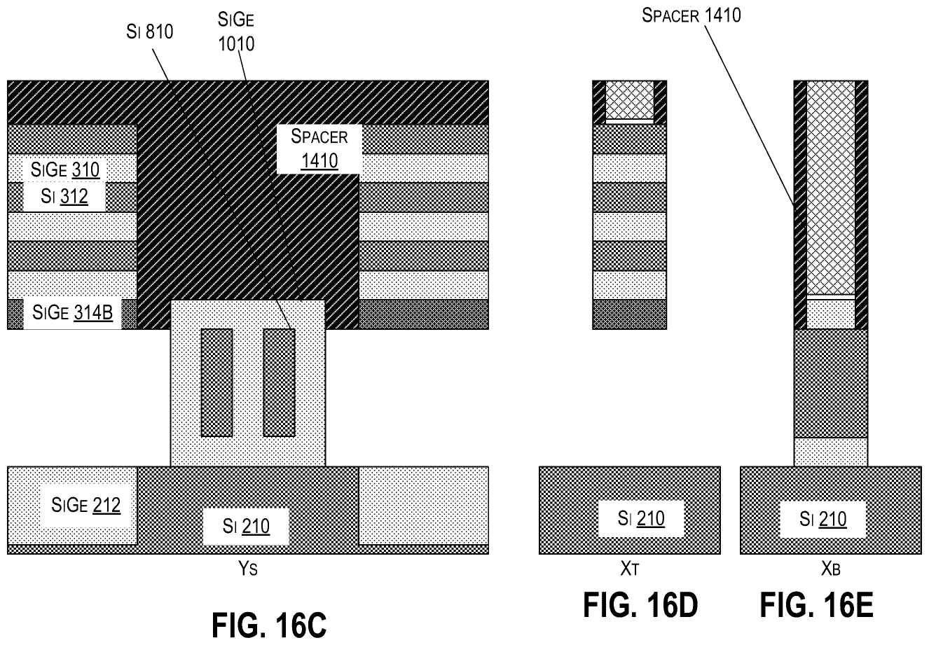

FIGS. 16A-16E illustrates a semiconductor device after the removal of the high-SiGe, in accordance with some embodiments. In some embodiments, the SiGe with high concentration of Ge is removed.

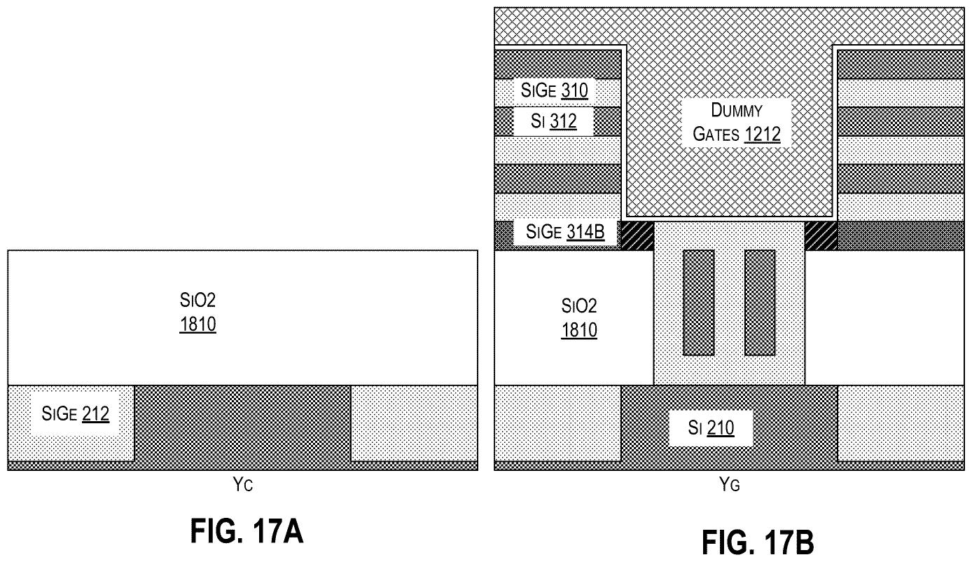

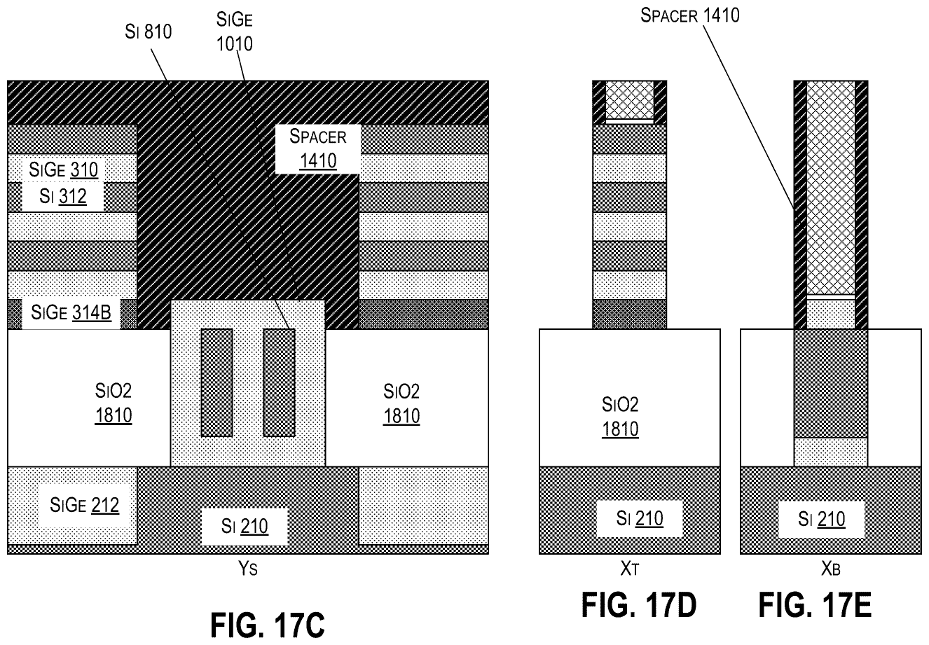

FIGS. 17A-17E illustrate a semiconductor device after the forming the silicon oxide, in accordance with some embodiments. In some embodiments, an SiO2 1810 fills the removed SiGe with high Ge concentration.

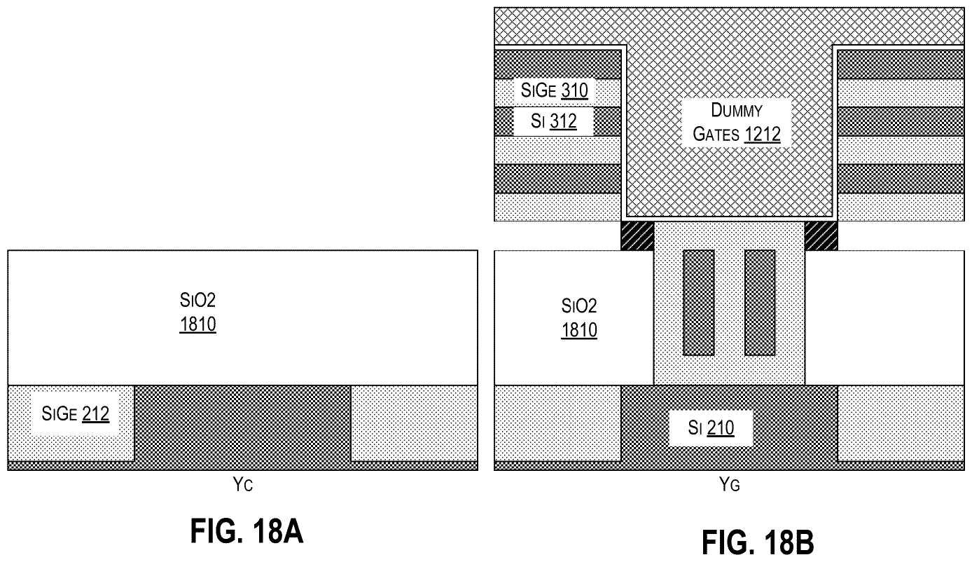

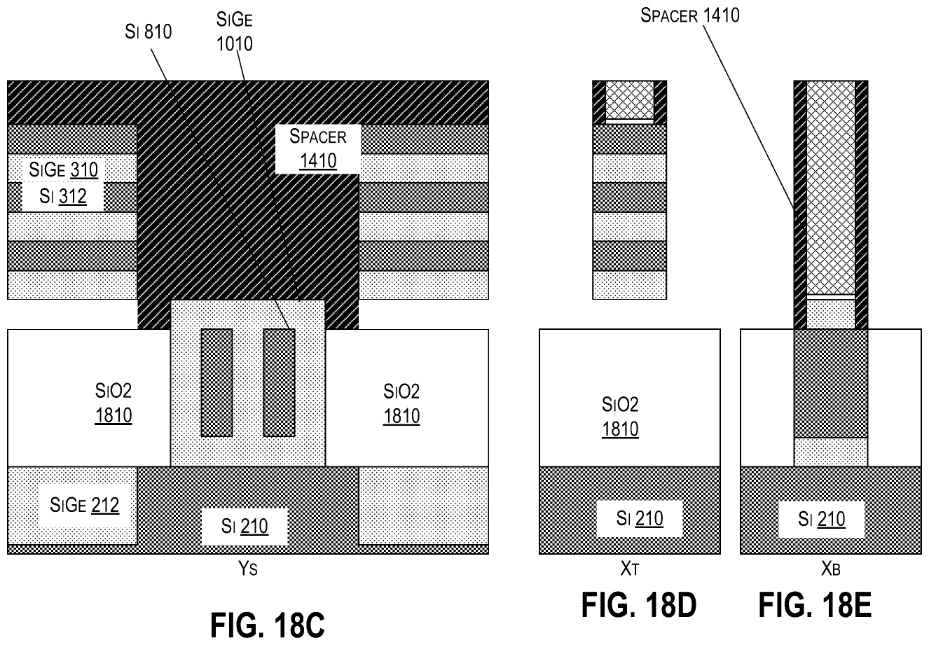

FIG. 18A-18E illustrate a semiconductor device after the removal of SiGe, in accordance with some embodiments. In some embodiments, the lowermost SiGe is removed.

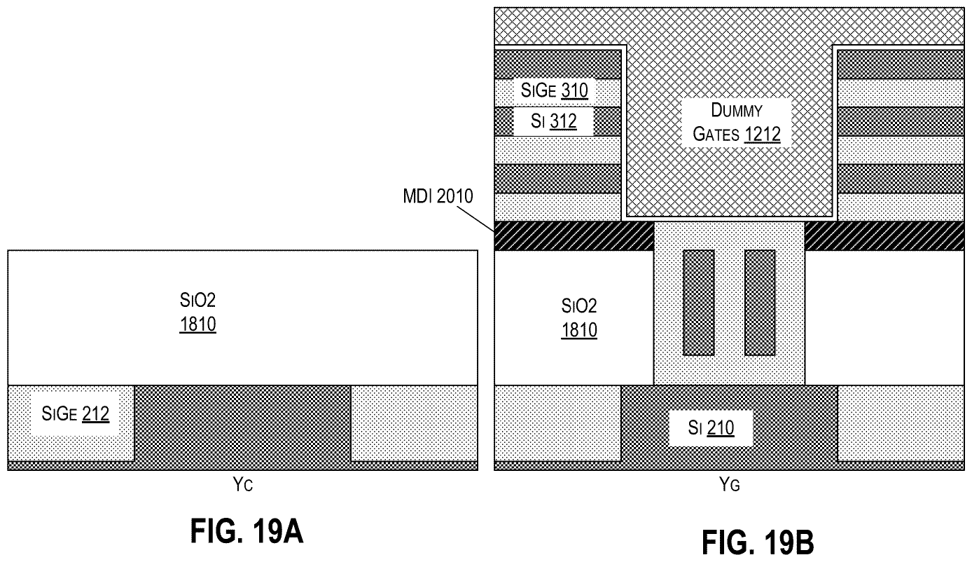

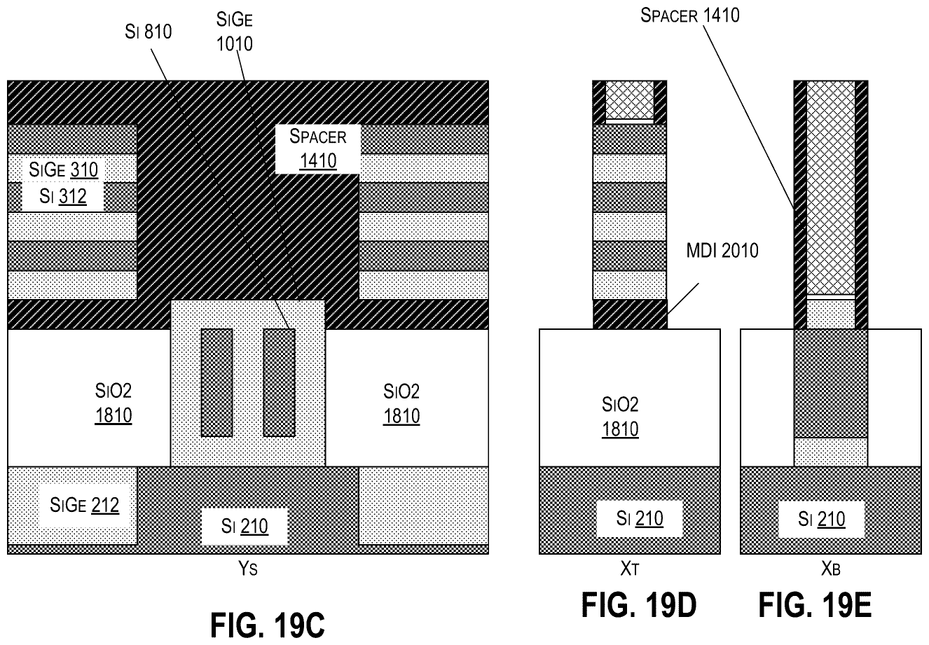

FIGS. 19A-19E illustrate a semiconductor device after the formation of middle dielectric isolation, in accordance with some embodiments. In some embodiments, a middle dielectric isolation, MDI 2010, fills the removed SiGe layer.

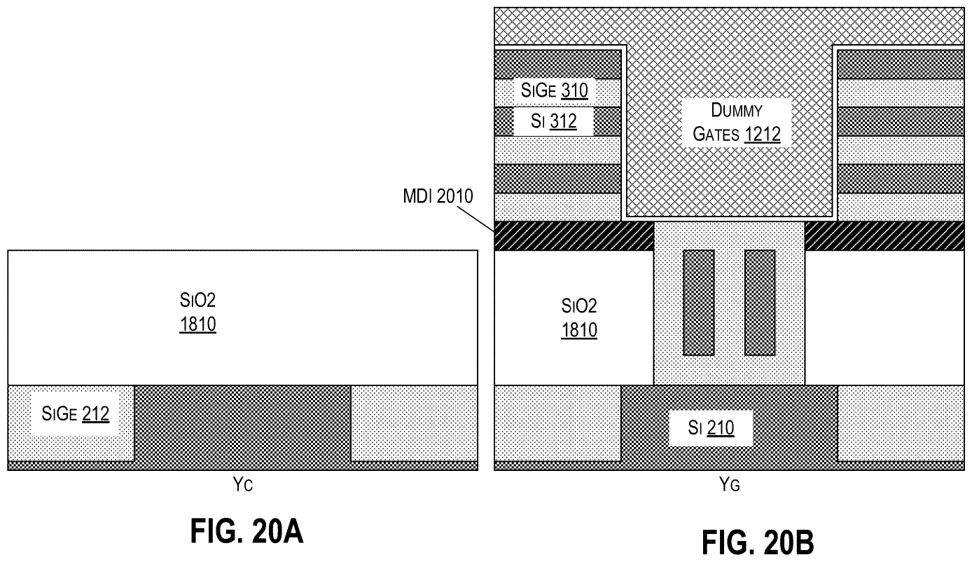

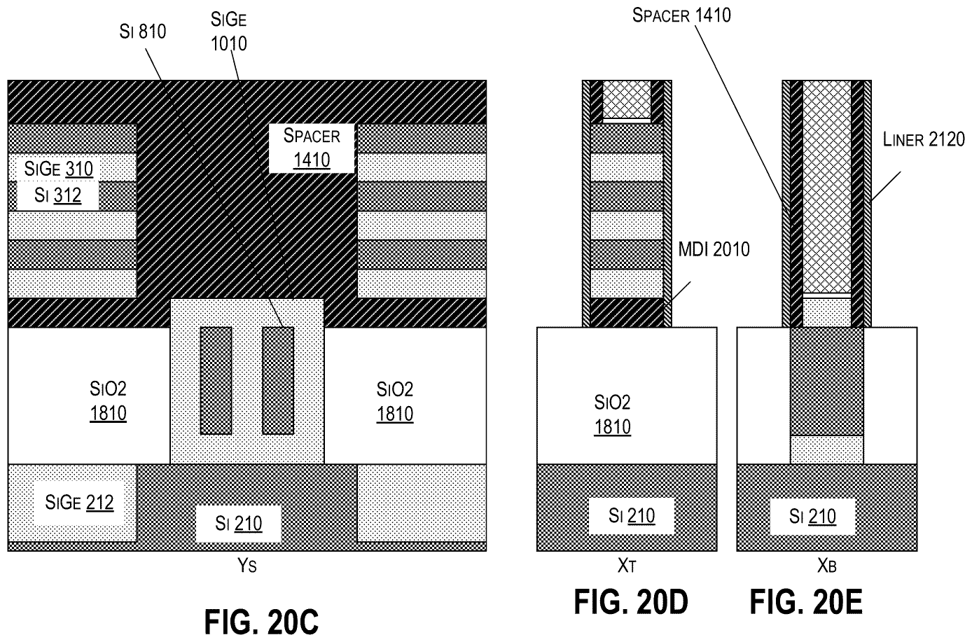

FIGS. 20A-20E illustrate a semiconductor device after the formation of liner, in accordance with some embodiments. In some embodiments, a liner 2120 is formed over the stacked over the substrate 210.

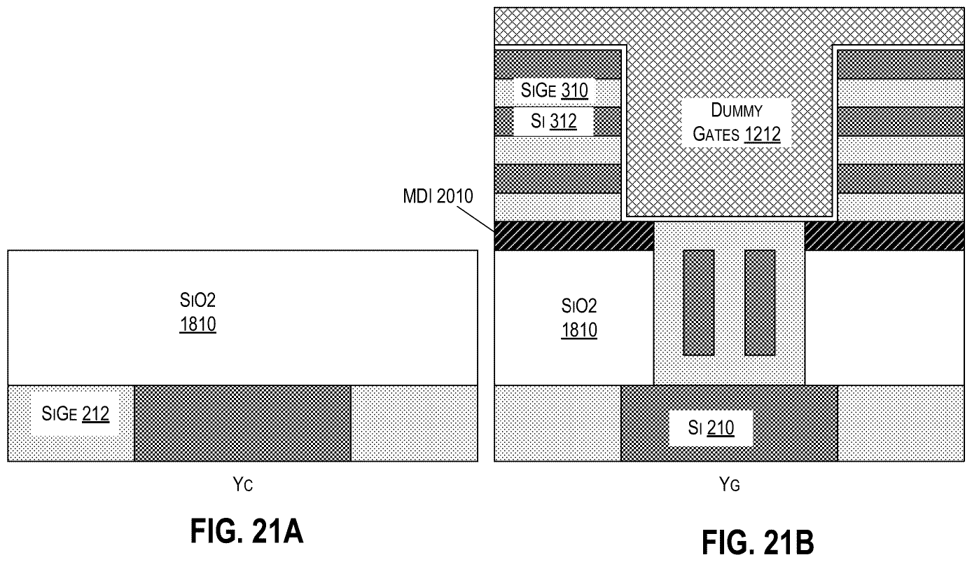

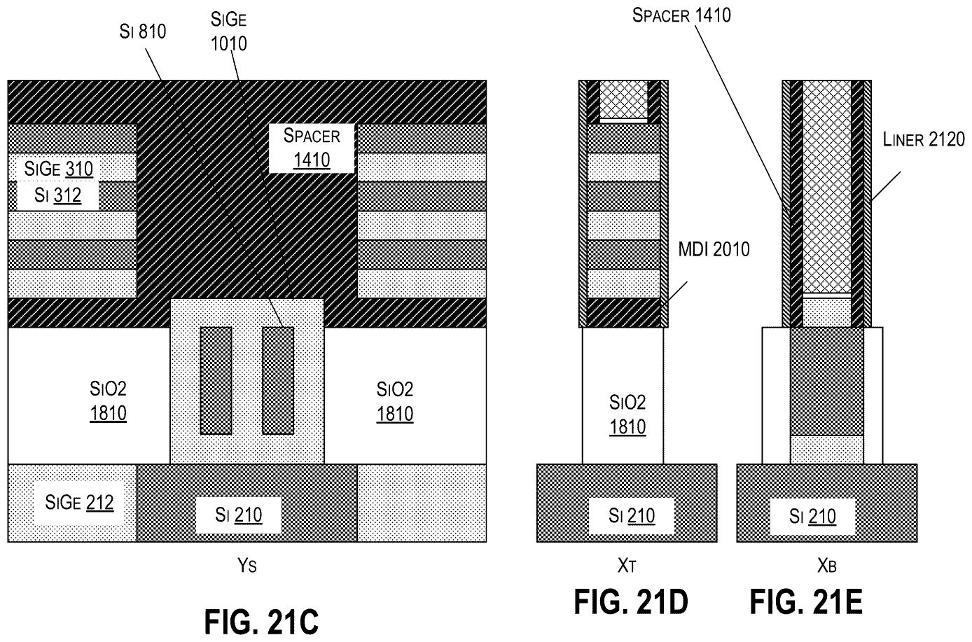

FIGS. 21A-21E illustrate a semiconductor device after the patterning of the silicon oxide, in accordance with some embodiments. In some embodiments, portions of the SiO2 1810 are removed so the stacks over the substrate 210 have a uniform width.

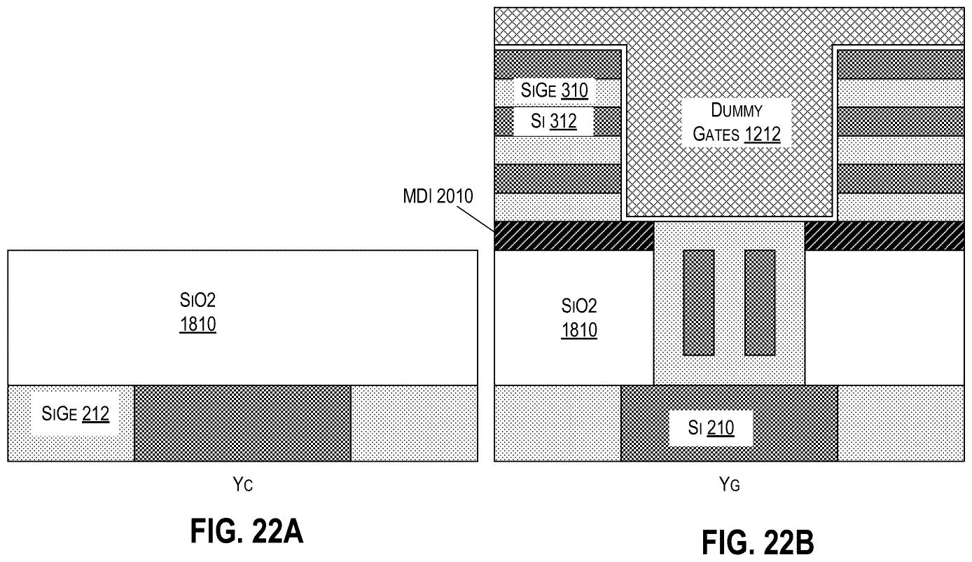

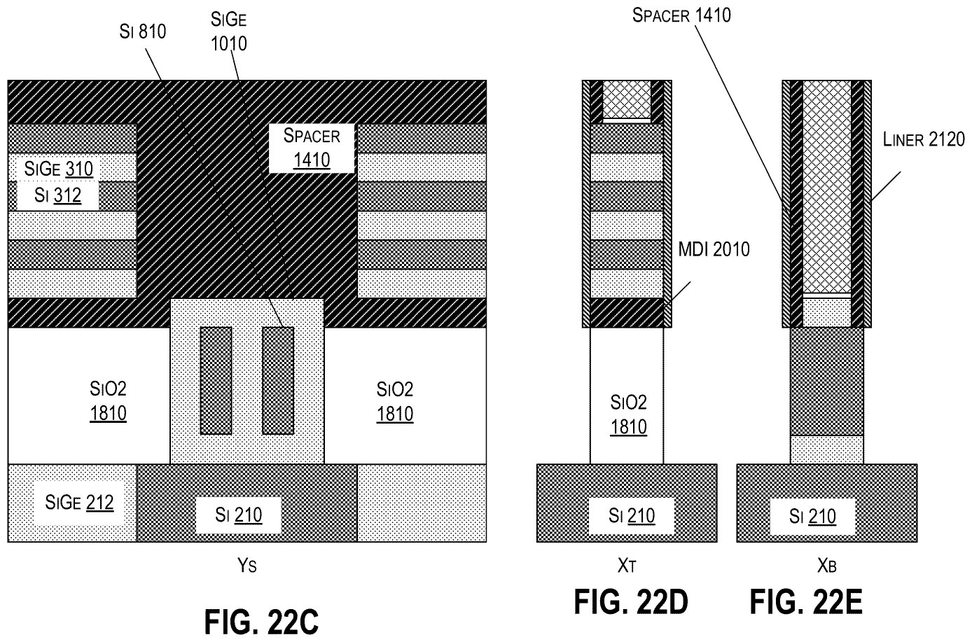

FIGS. 22A-22E illustrate a semiconductor device after the removing of a lower portion of the stacks, in accordance with some embodiments. In some embodiments, the lower portions of the stacks over the substrate 210 are etched back to further narrow the width.

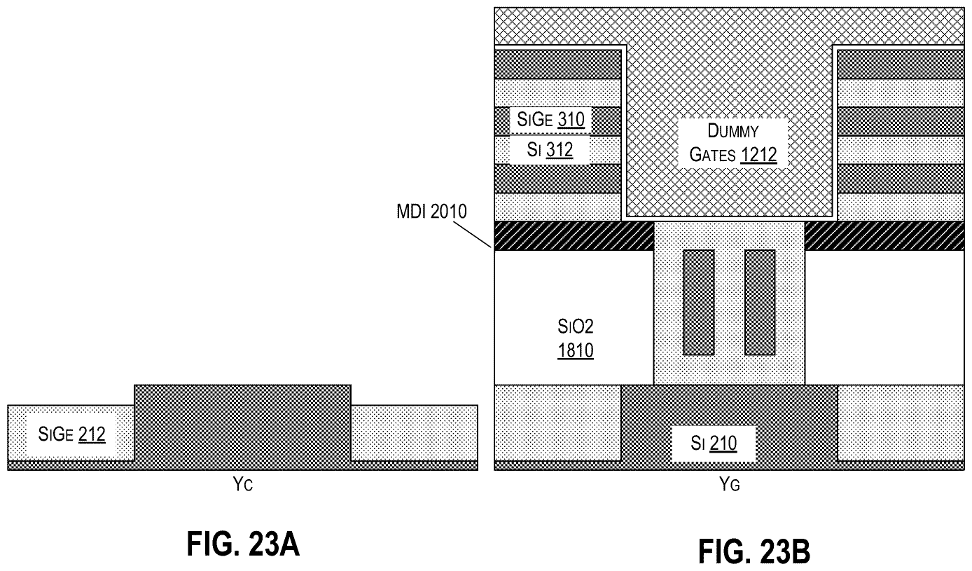

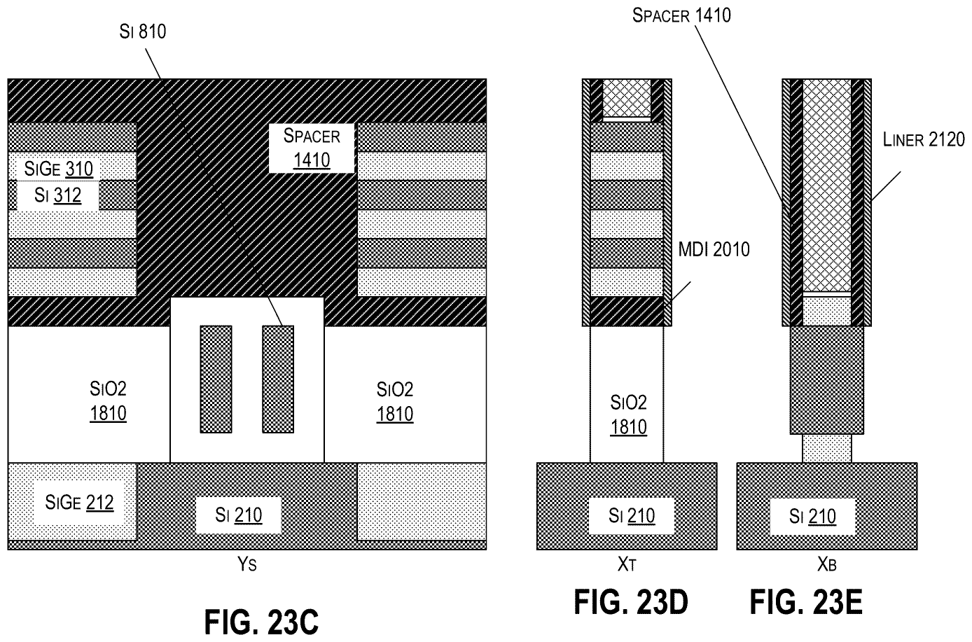

FIGS. 23A-23E illustrate a semiconductor device after the removal of a SiGe, in accordance with some embodiments. In some embodiments, the SiGe encapsulating the Si 810 is removed.

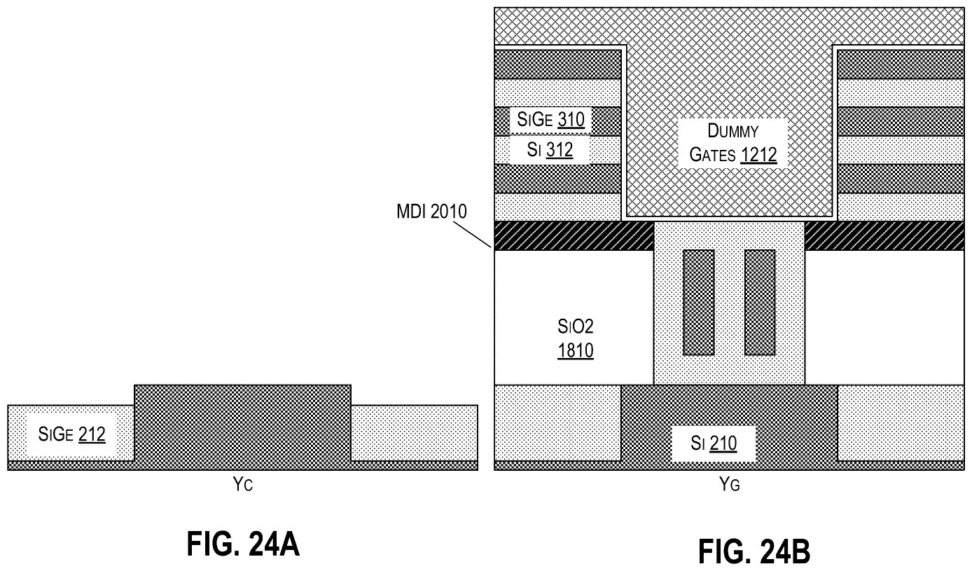

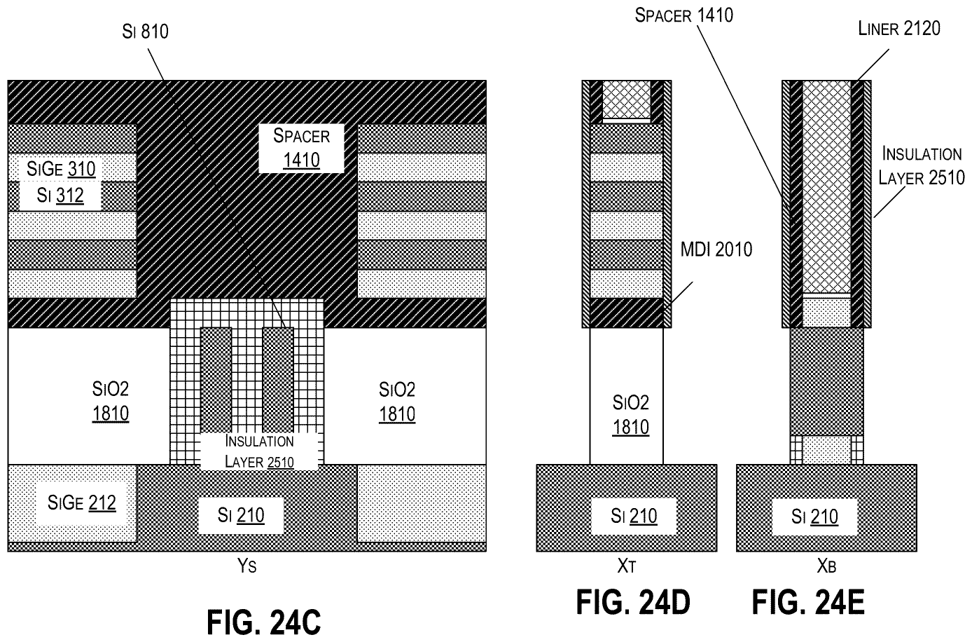

FIGS. 24A-24E illustrates a semiconductor device after the formation of an insulation layer, in accordance with some embodiments. In some embodiments, an insulation layer 2510 encapsulates the Si 810 and covers sidewalls of the lowermost SiGe layer over the substrate 210.

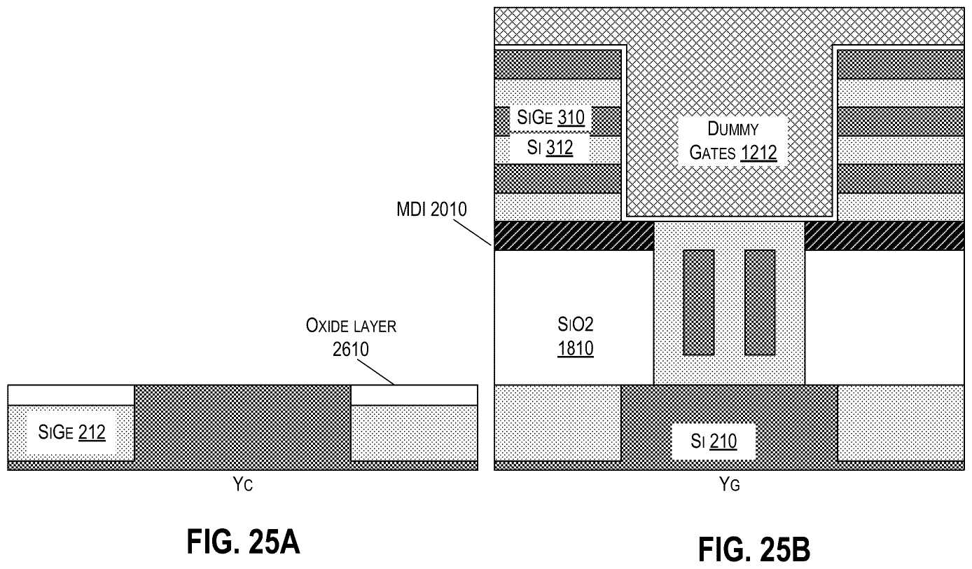

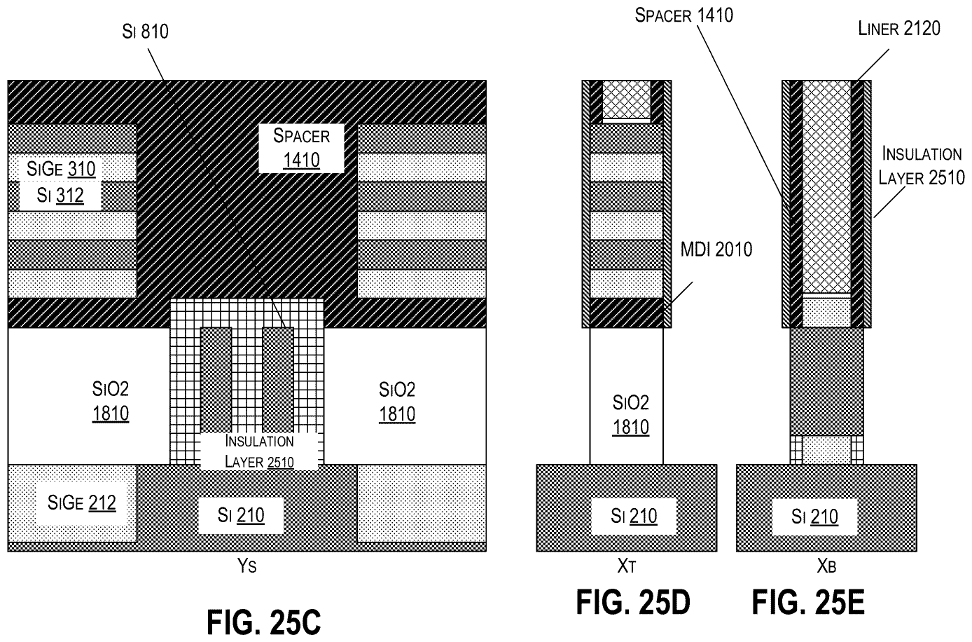

FIGS. 25A-25E illustrate a semiconductor device after the formation of an oxide layer, in accordance with some embodiments. In some embodiments, an oxide layer 2610 is formed over the SiGe 212.

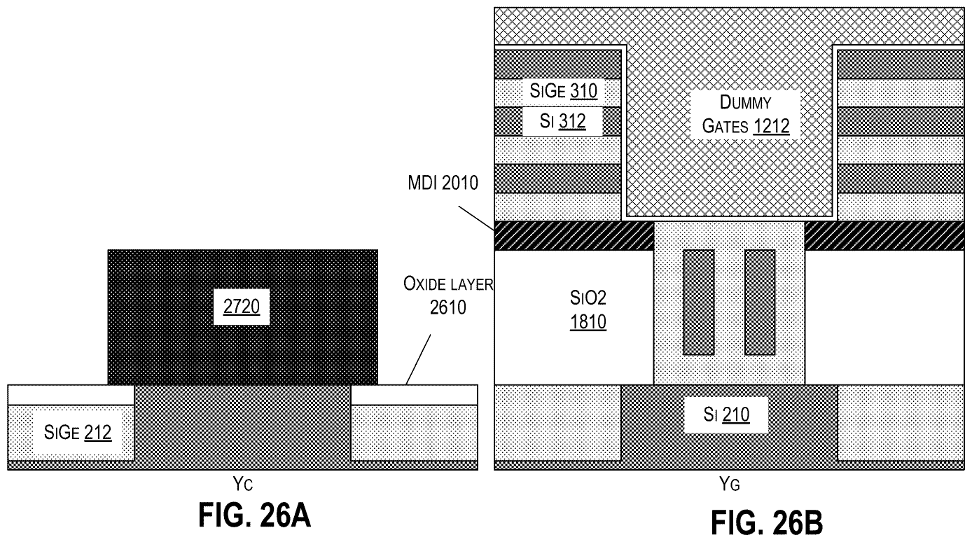

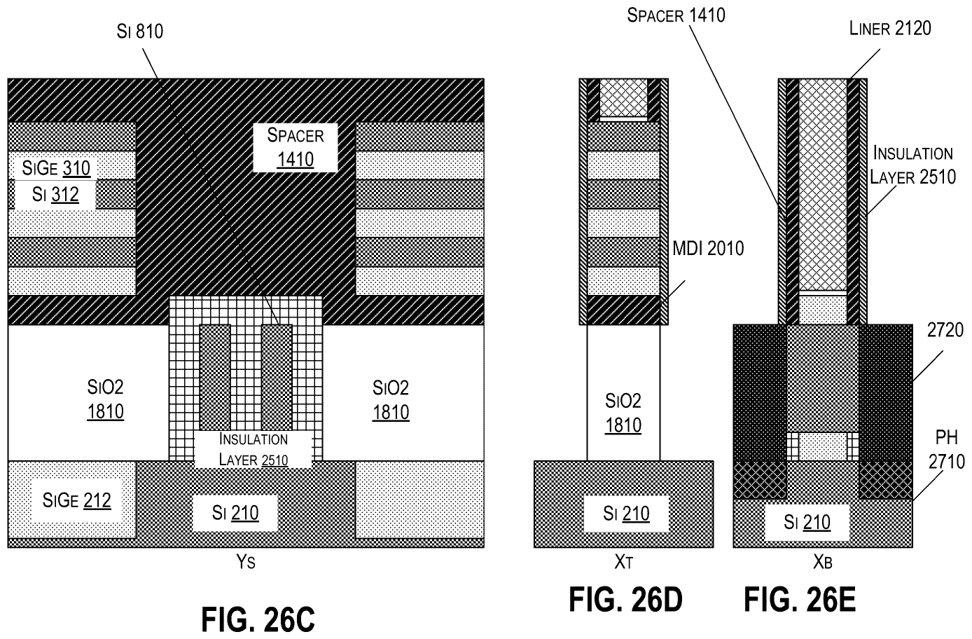

FIGS. 26A-26E illustrate a semiconductor device after the formation of placeholders and bottom source/drain regions, in accordance with some embodiments. In some embodiments, placeholders, PH 2710 are formed. The bottom source/drain regions 2720 are formed over the PH 2710.

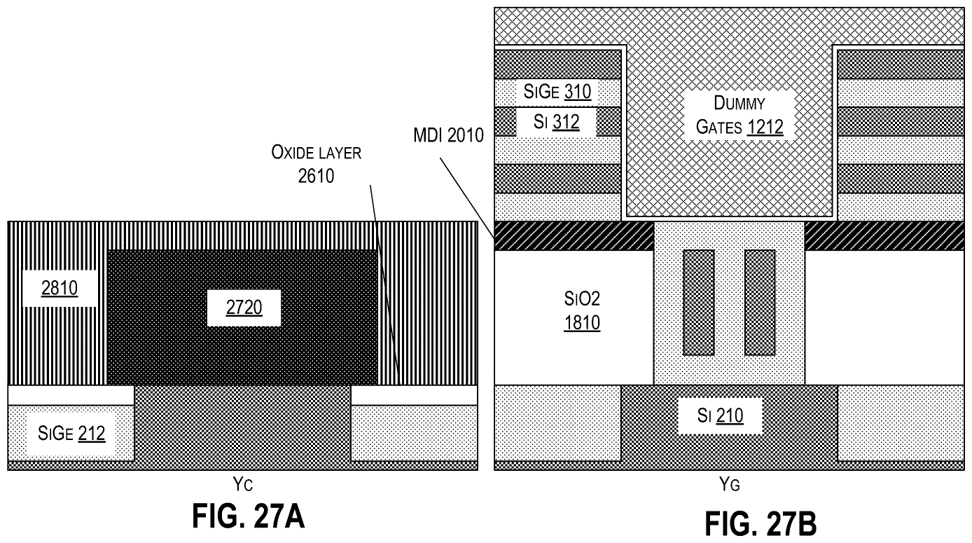

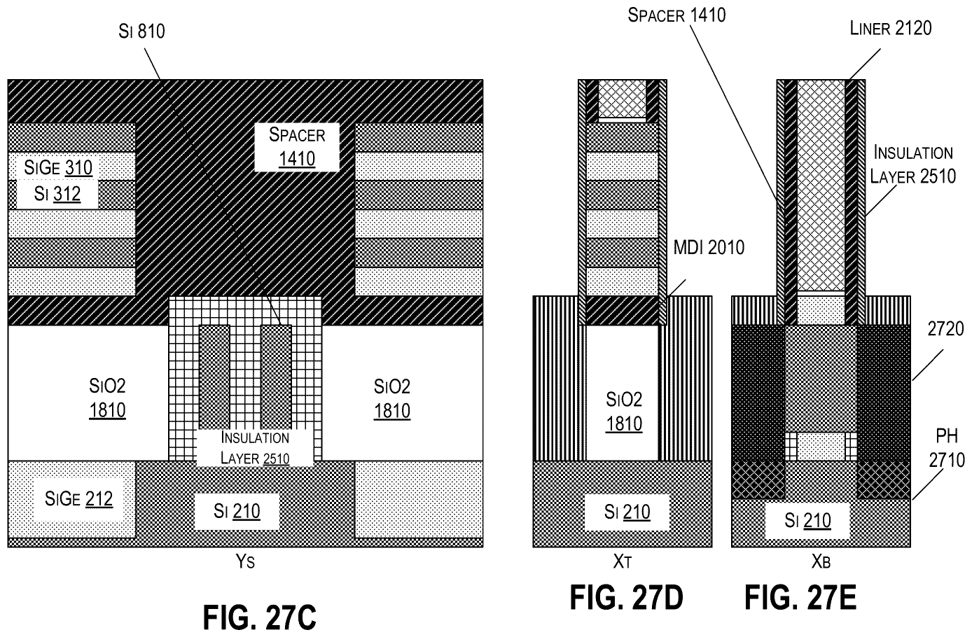

FIGS. 27A-27E illustrate a semiconductor device after the formation of silicon oxide, in accordance with some embodiments. In some embodiments, a layer of SiO2 2810 is formed over the source/drain regions 2720 and the substrate 210.

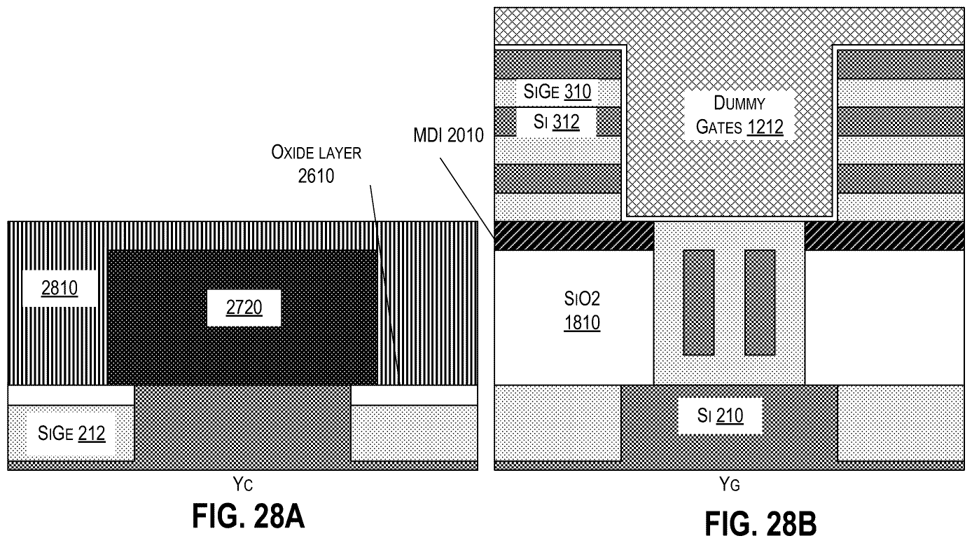

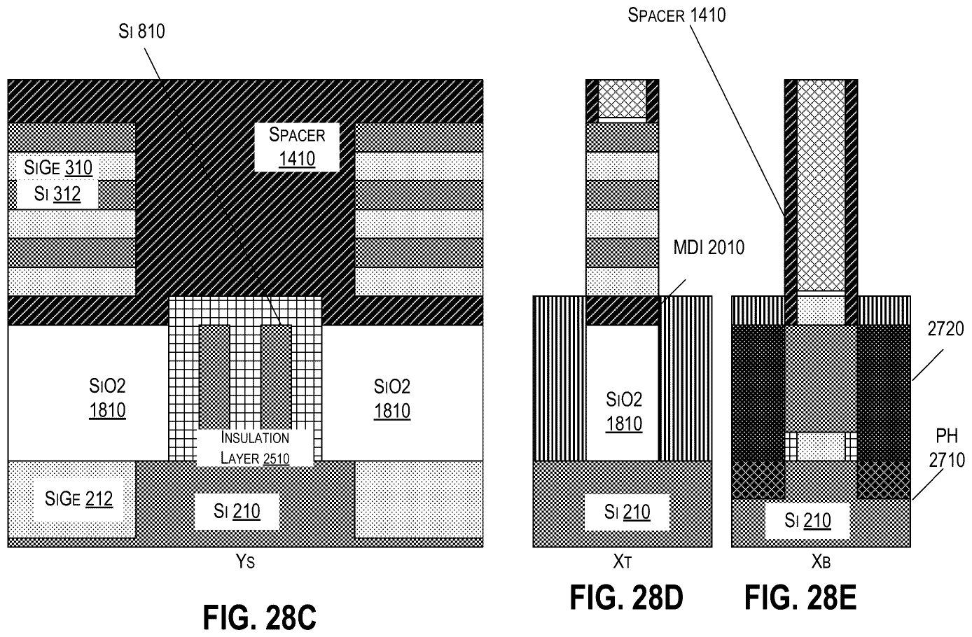

FIGS. 28A-28E illustrate a semiconductor device after the removal of the liner, in accordance with some embodiments. In some embodiments, the liner is removed.

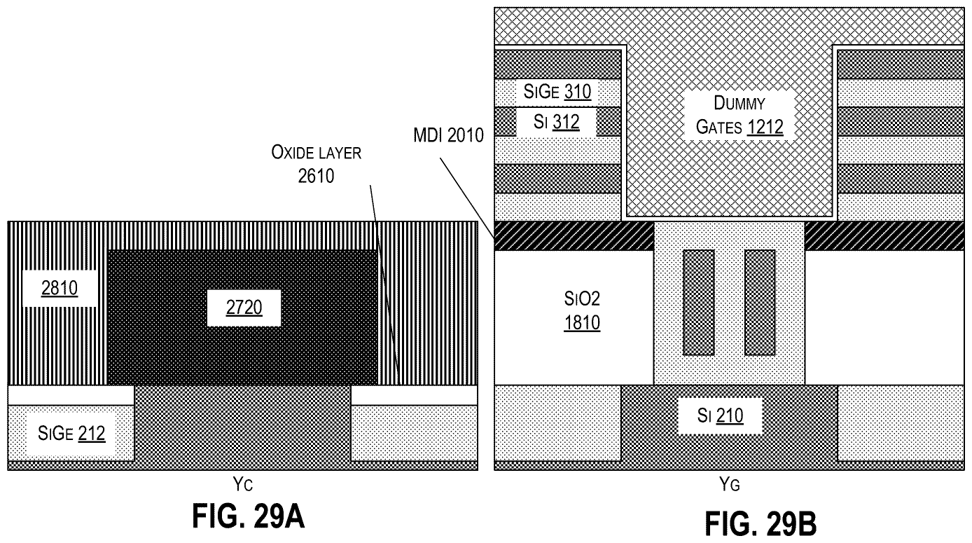

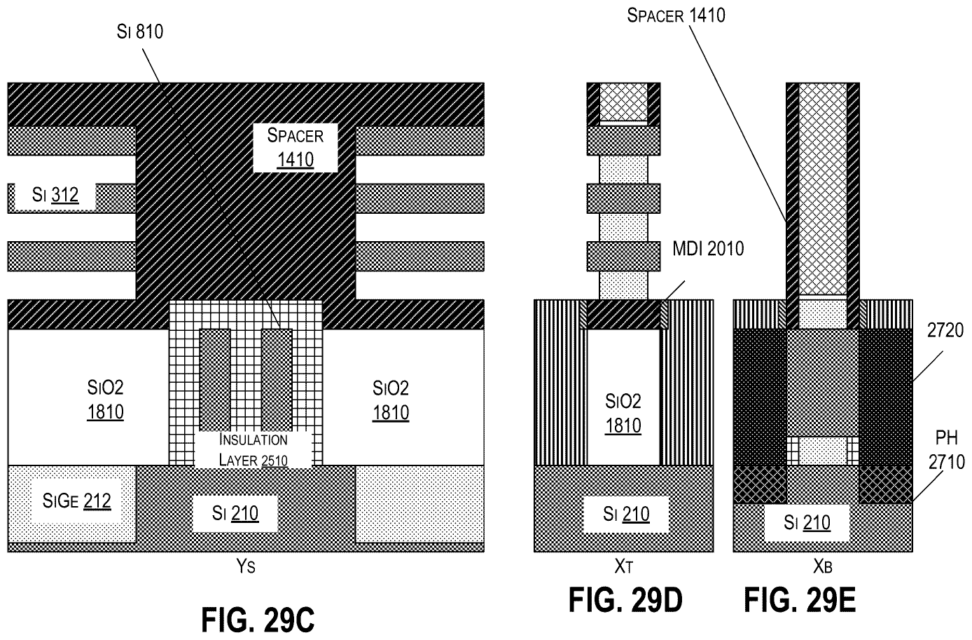

FIGS. 29A-29E illustrate a semiconductor device after the indentation of the insulation layer, in accordance with some embodiments. In some embodiments, the SiGe has been removed.

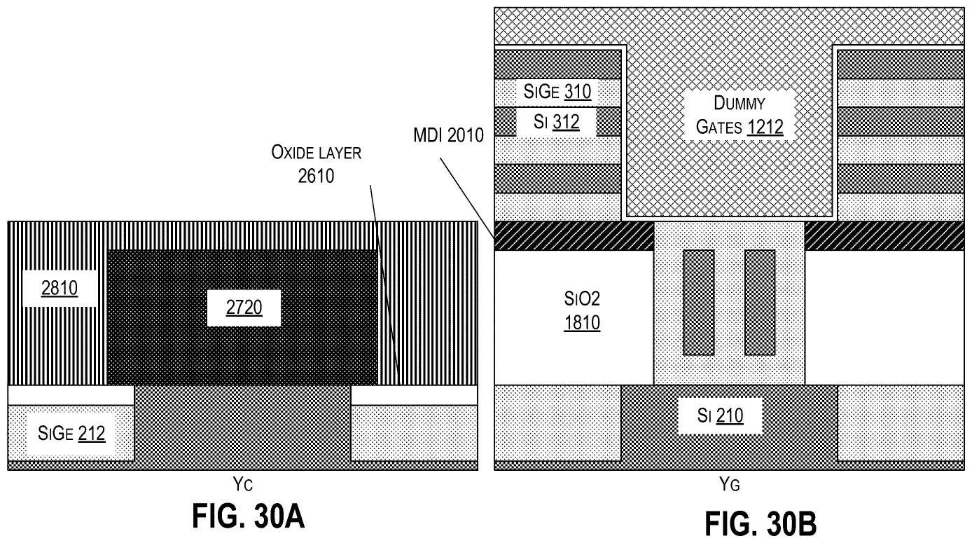

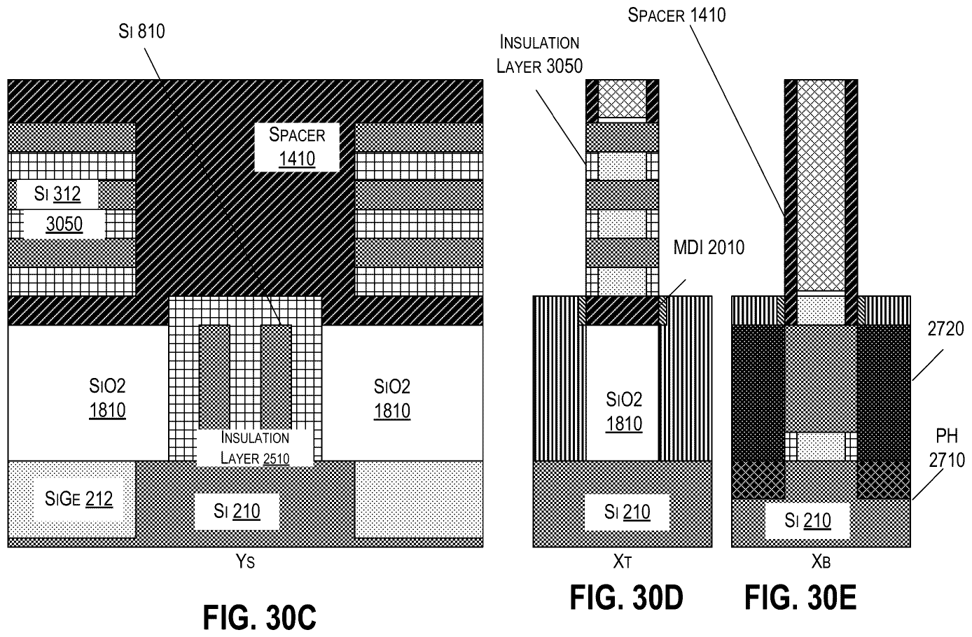

FIGS. 30A-30E illustrate a semiconductor device after the formation of the insulation layer, in accordance with some embodiments. In some embodiments, the insulation layer 3050 is formed to replace the SiGe layers.

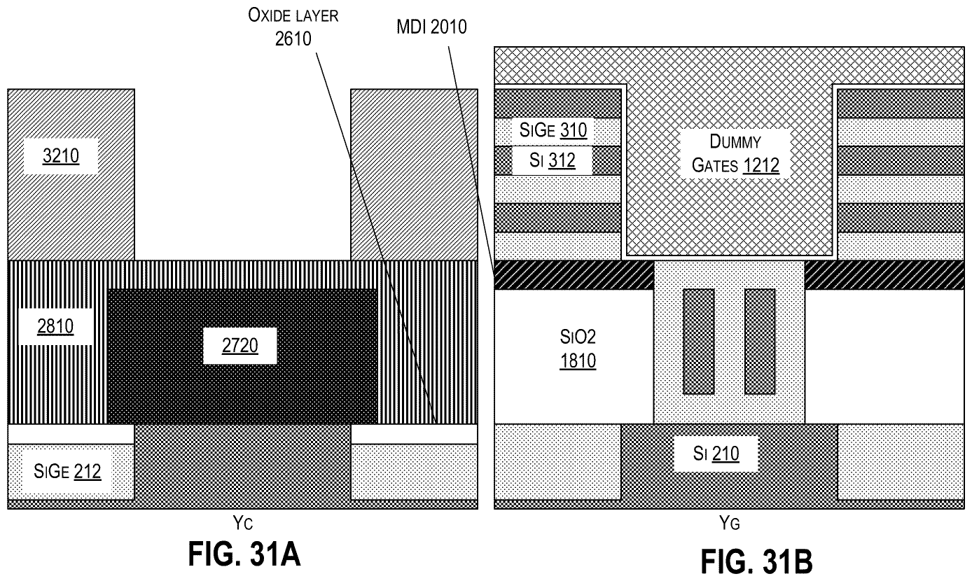

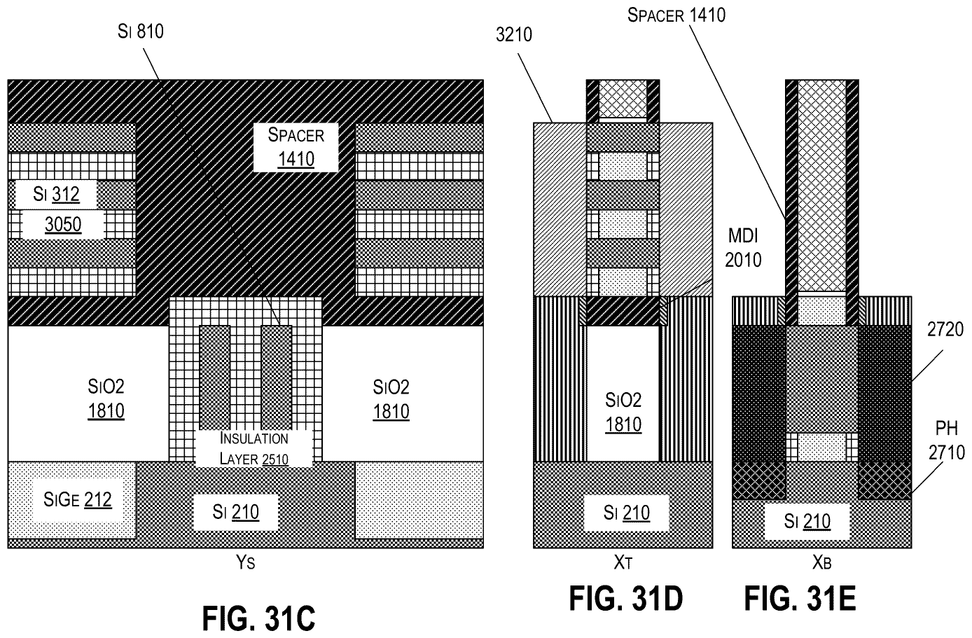

FIGS. 31A-31E illustrate a semiconductor device after the formation of top source/drain regions, in accordance with some embodiments. In some embodiments, the top source/drain regions 3210 are formed over the SiO2 2810. The top source/drain regions 3210 are not in contact with the bottom source/drain regions 2720.

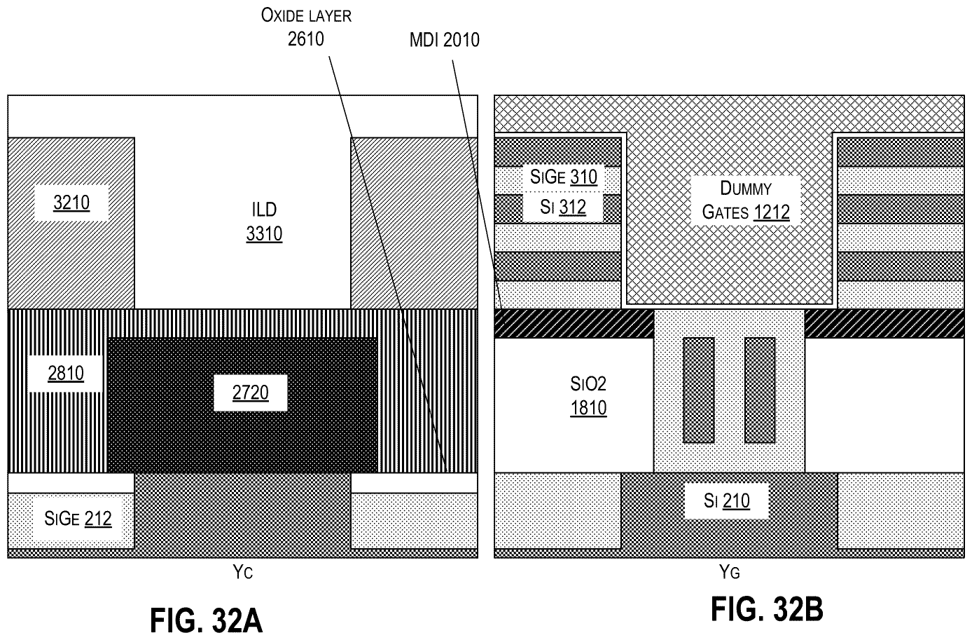

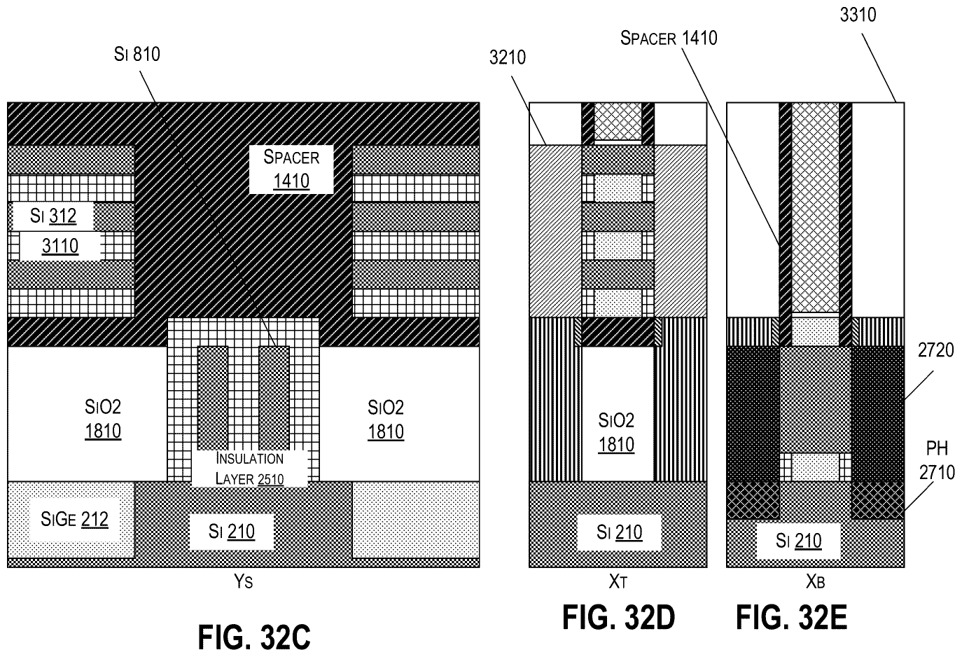

FIGS. 32A-32E illustrate a semiconductor device after the formation of interlayer dielectric, in accordance with some embodiments. In some embodiments, an ILD 3310 is formed over the top source/drain regions 3210.

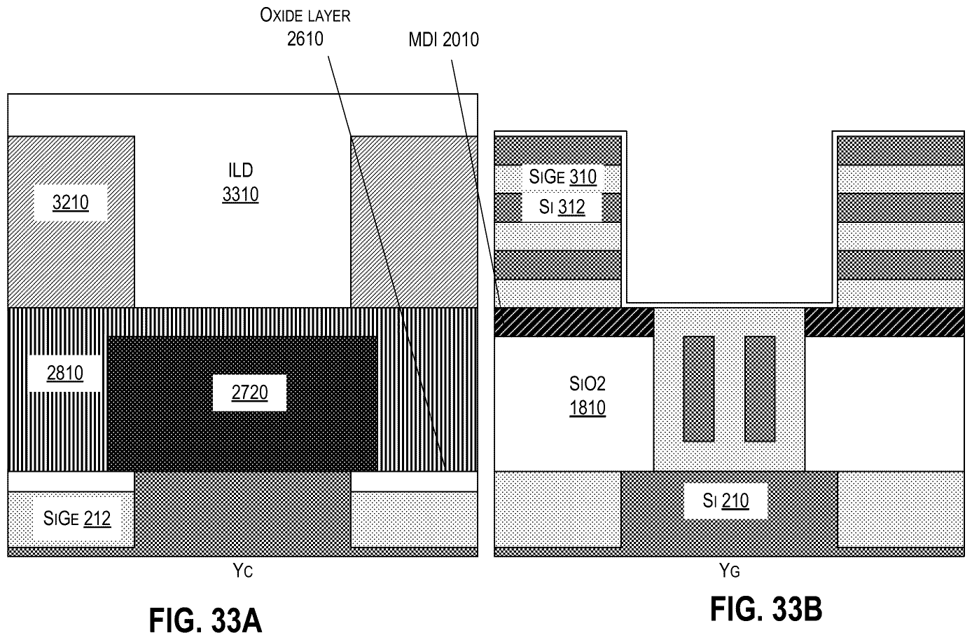

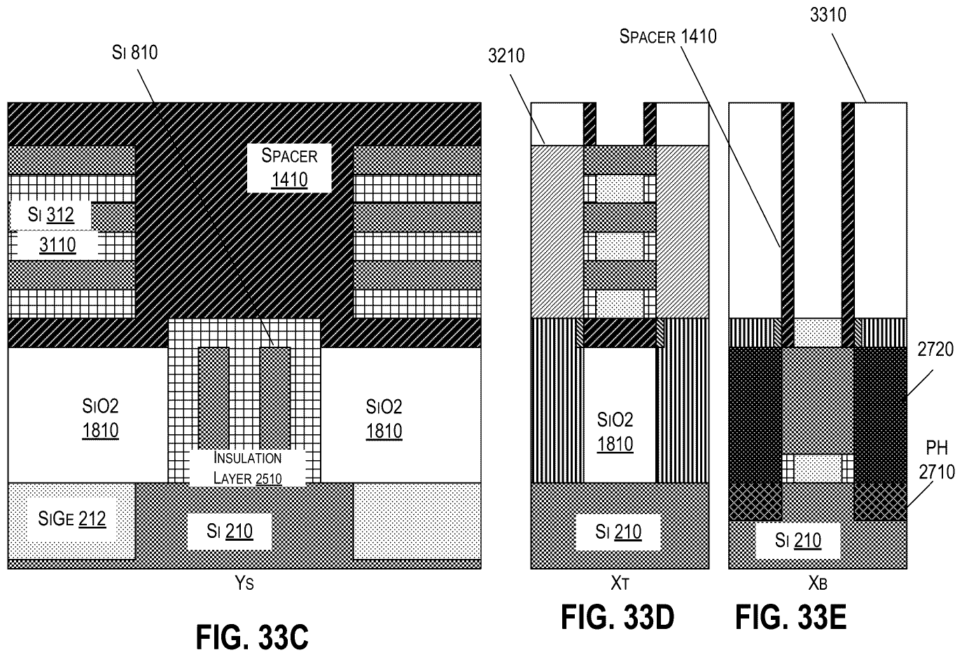

FIGS. 33A-33E illustrate a semiconductor device after the removal of the dummy gates, in accordance with some embodiments. In some embodiments, the remaining dummy gates are removed.

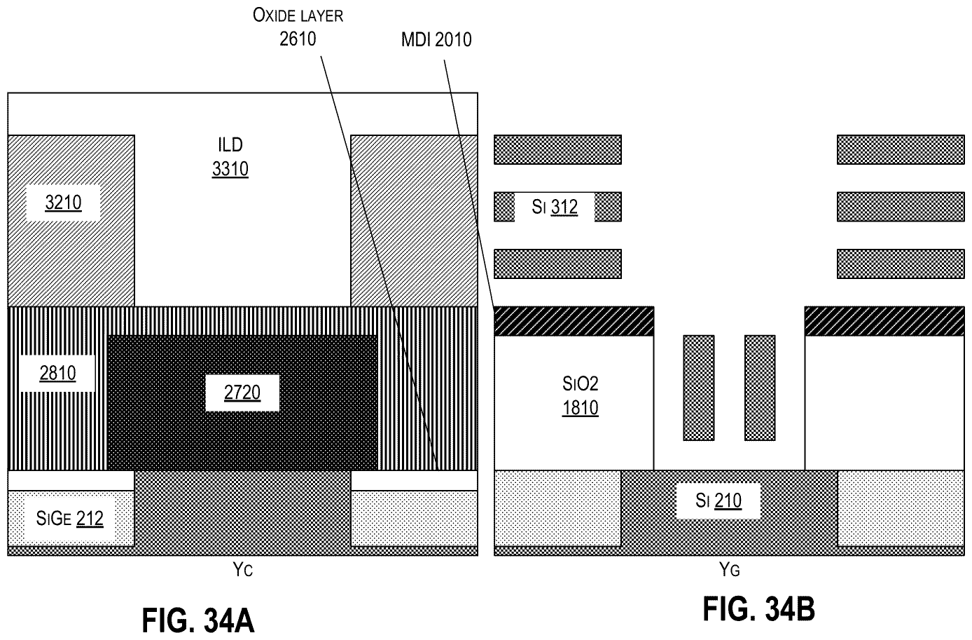

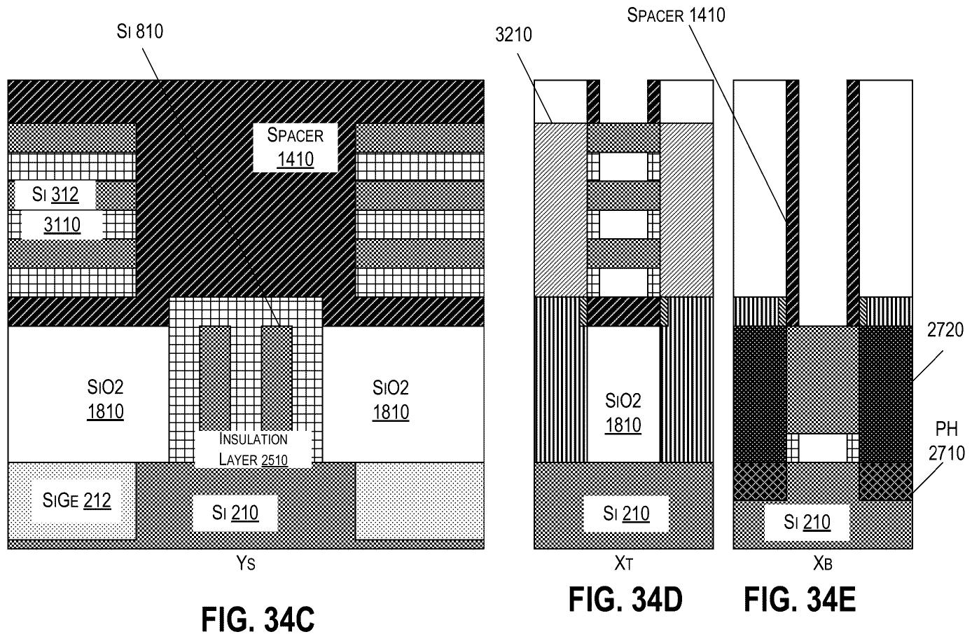

FIGS. 34A-34E illustrate a semiconductor device after the removal of the SiGe in the channel region, in accordance with some embodiments. In some embodiments, the remaining SiGe in the channel region are removed.

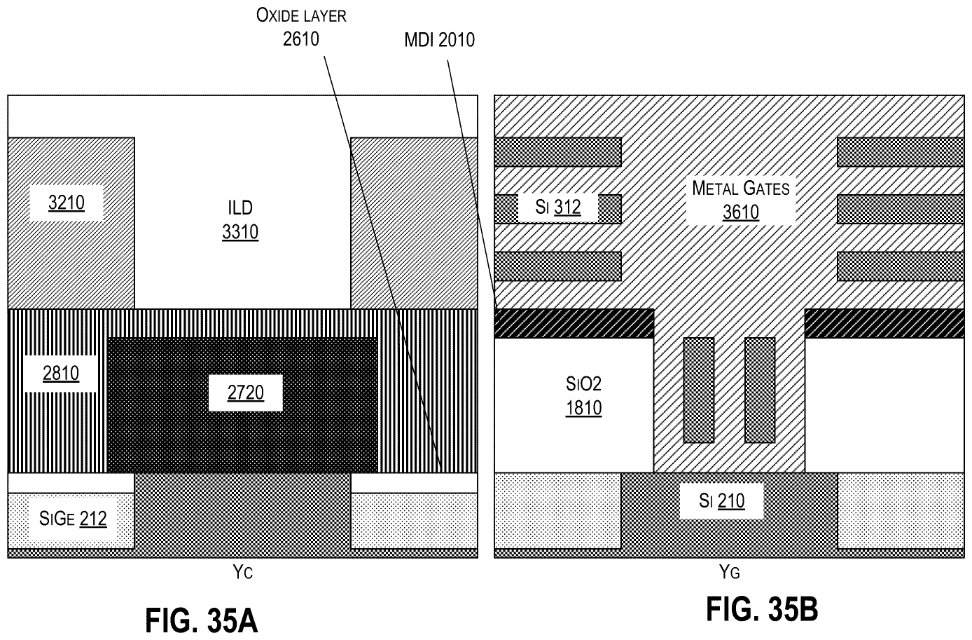

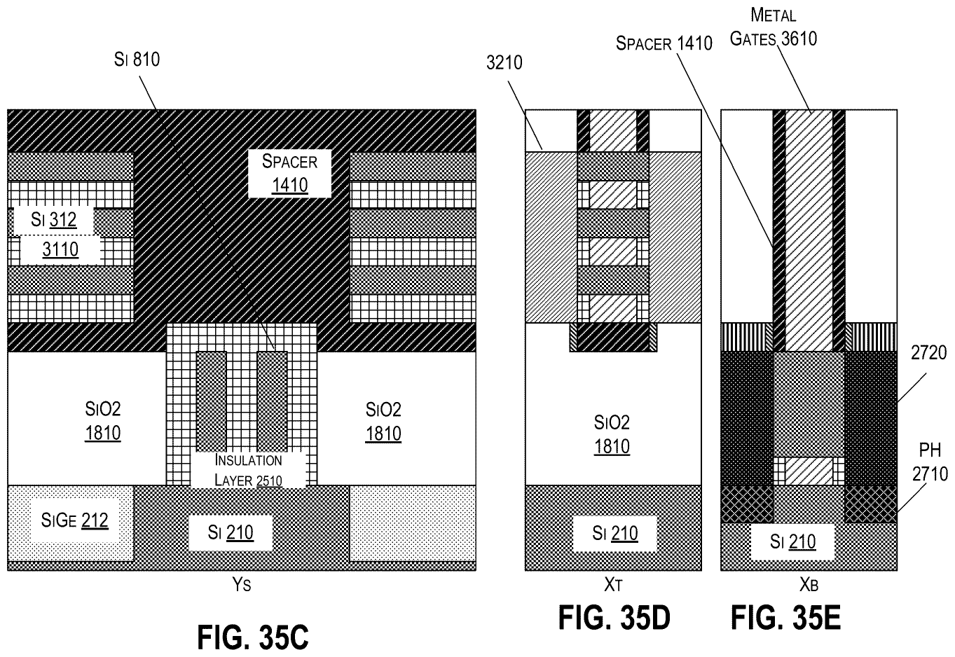

FIGS. 35A-35E illustrate a semiconductor device after the metallization of the channel regions, in accordance with some embodiments. In some embodiments, a replacement metal gate (RMG) process can be used to fabricate metal gates 3610. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

In various embodiments, the gate regions 3610 serve as control elements that regulate the flow of current through the semiconductor device. The gate regions 3610 can be composed of a conductive material. The gate regions 3610 can control the flow of electric current between the source and drain regions. In addition to acting as a switch, modulating the gate voltage can enable the gate regions 3610 to control the current flowing through the channel region, resulting in amplified output signals.

In an embodiment, the gate regions 3610 can enable the implementation of Boolean active operations, such as AND, OR, and NOT, by controlling the flow of current based on the input voltages. In some embodiments, the gate regions 3610, along with other active device components, can facilitate the miniaturization and integration of electronic circuits. The ability to control the channel region's conductivity through the gate voltage allows for compact and highly efficient circuit designs.

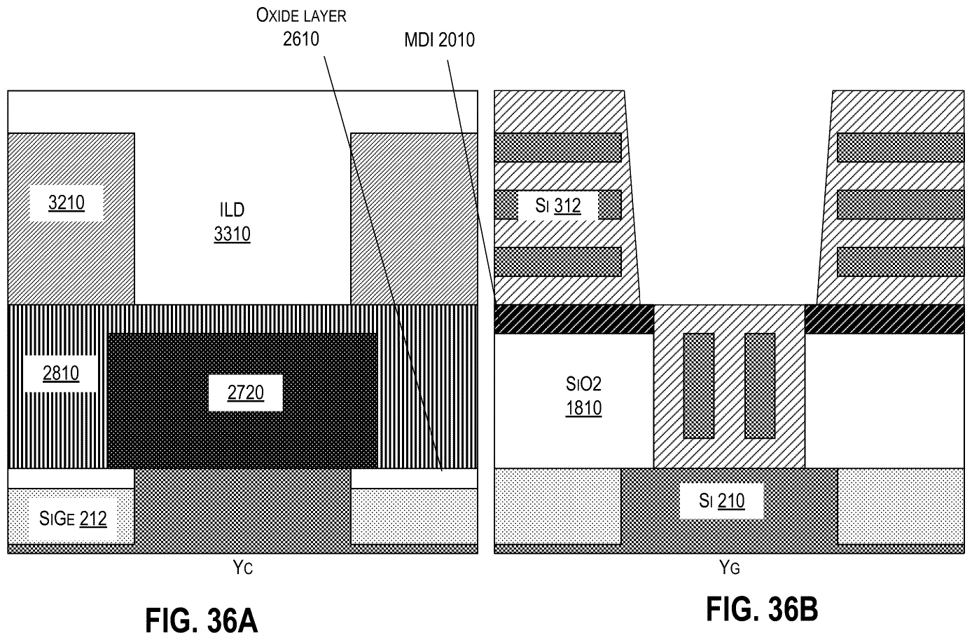

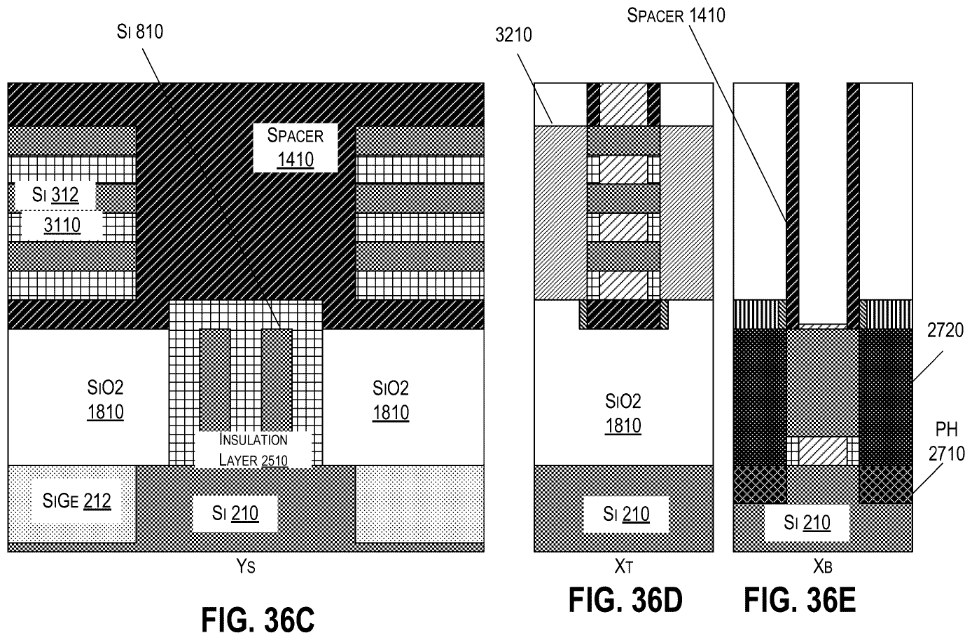

FIGS. 36A-36E illustrate a semiconductor device after the partial removal of the channel regions, in accordance with some embodiments. In some embodiments, portions of the channel regions are removed.

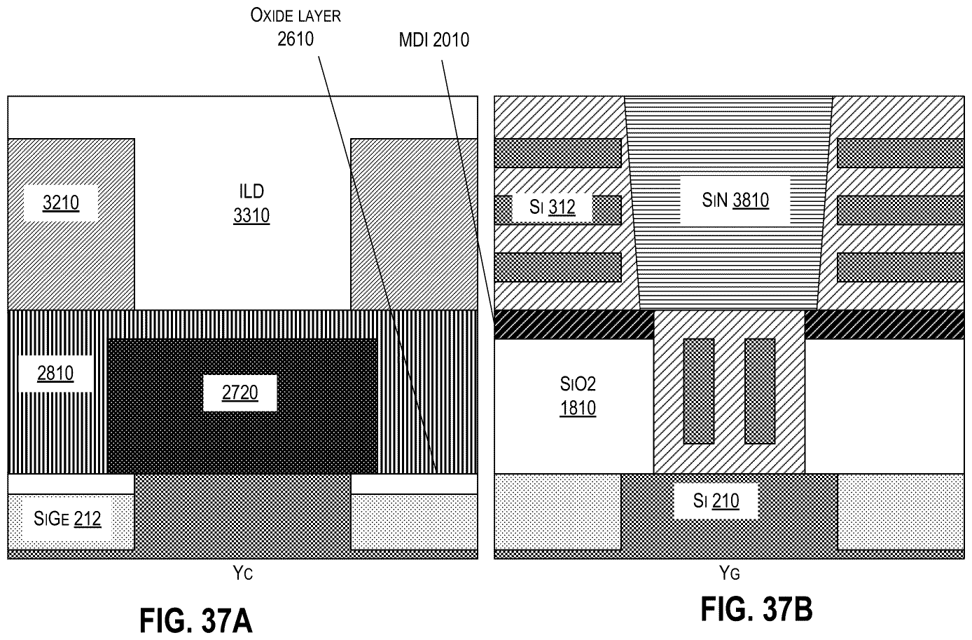

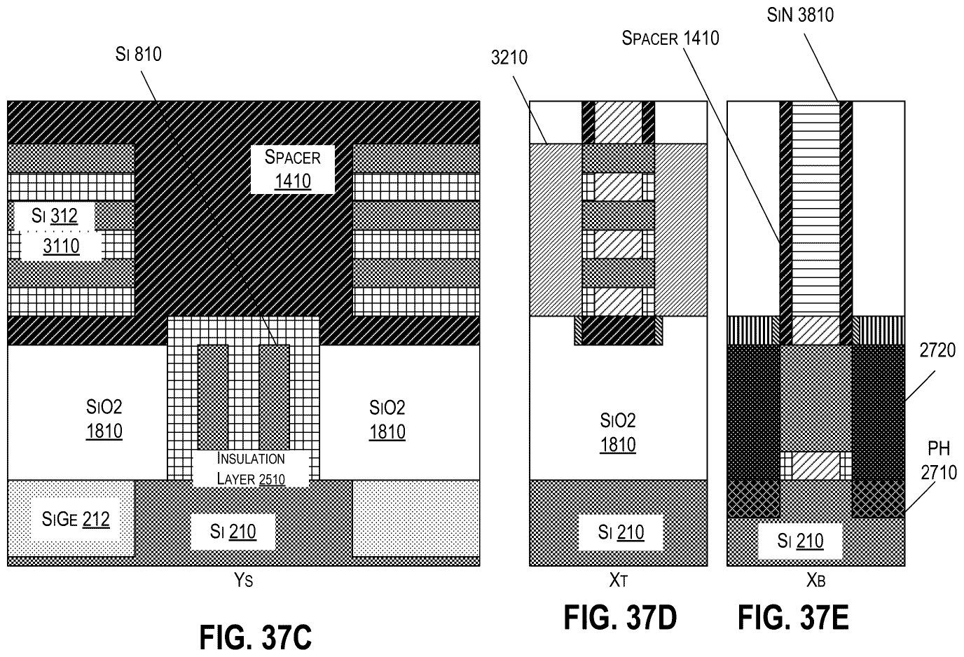

FIGS. 37A-37E illustrate a semiconductor device after the filling of the channel regions, in accordance with some embodiments. In some embodiments, the removed portions of the channel regions are filled with SiN 3810.

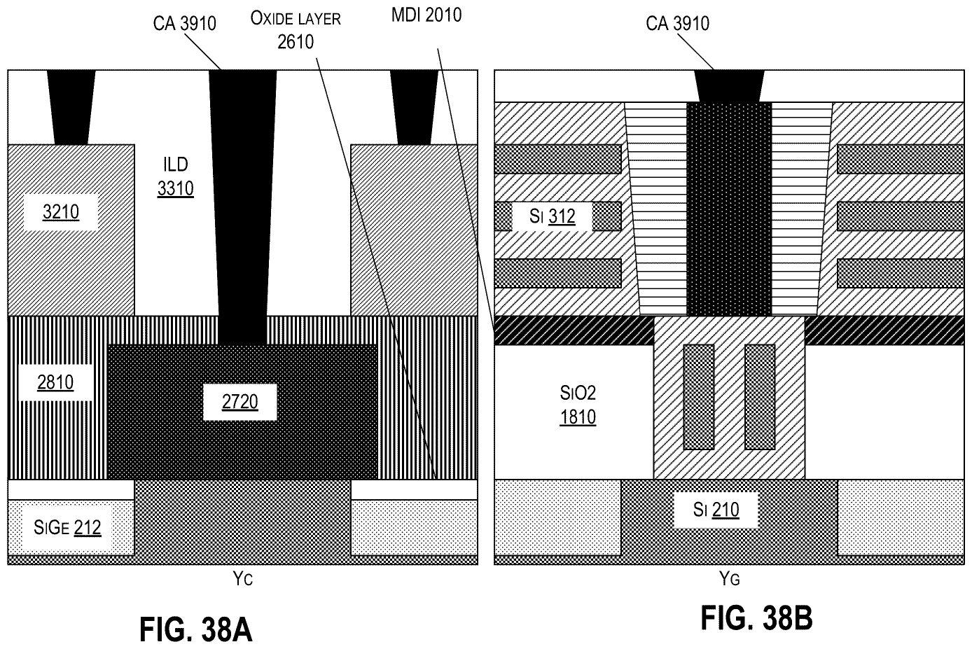

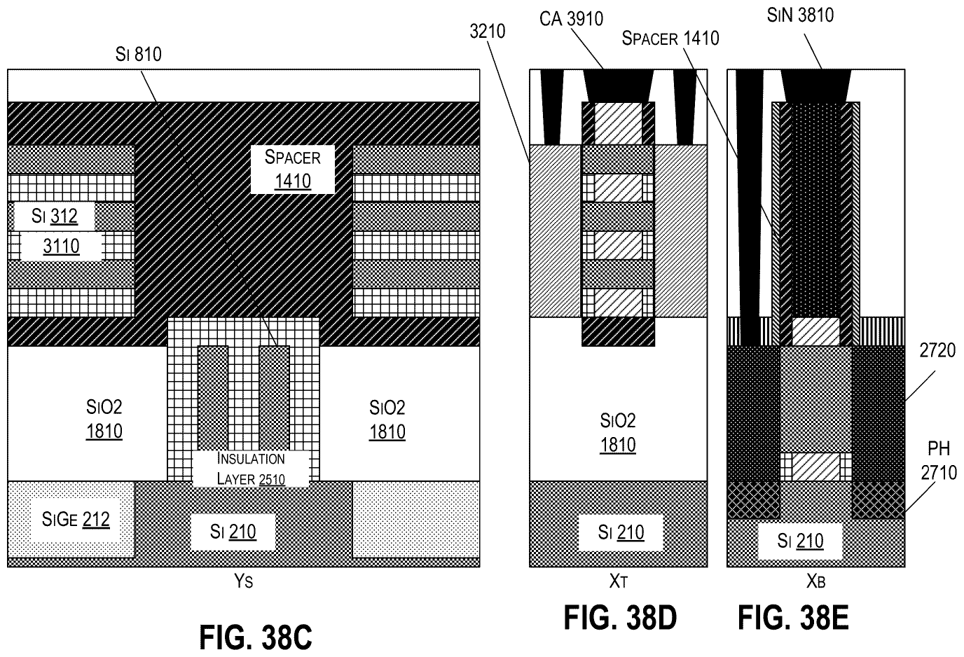

FIGS. 38A-38E illustrate a semiconductor device after the formation of contacts, in accordance with some embodiments. In some embodiments, contacts, CA 3910, are formed to connect the source/drain regions to the BEOL.

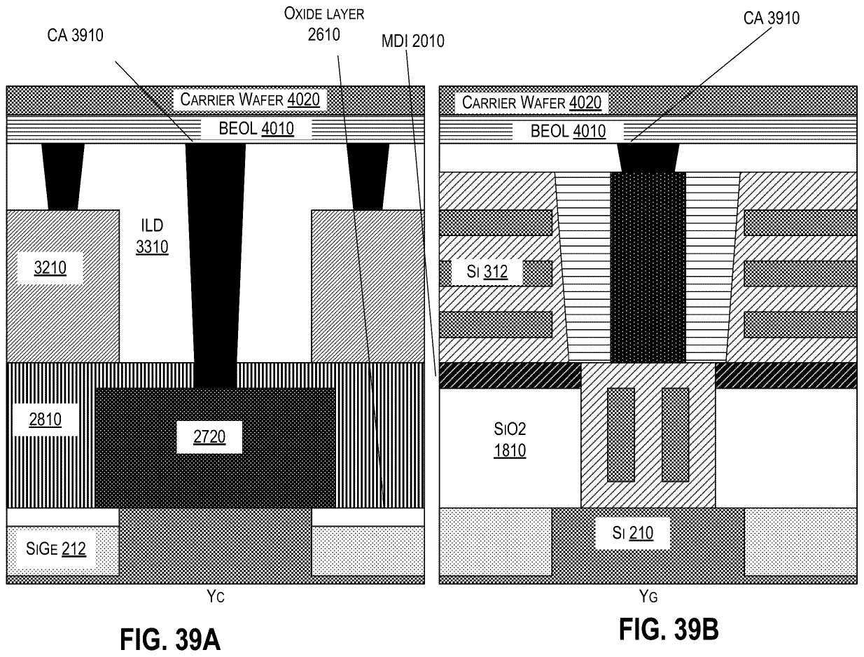

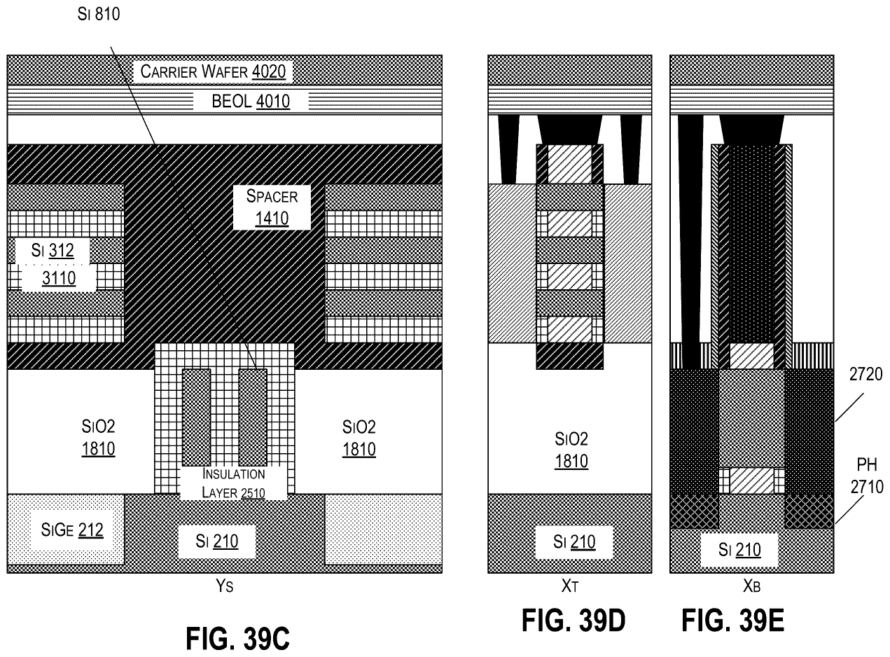

FIGS. 39A-39E illustrate a semiconductor device after the formation of the back end of line and wafer bonding, in accordance with some embodiments. In some embodiments, a back end of line, BEOL 4010, is formed which can include interconnects and wires to connect the semiconductor device to other chips. In some embodiments, carrier wafer bonding, also known as wafer-to-wafer bonding or chip-to-wafer bonding, is performed to join two semiconductor devices via a carrier wafer 4020 together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

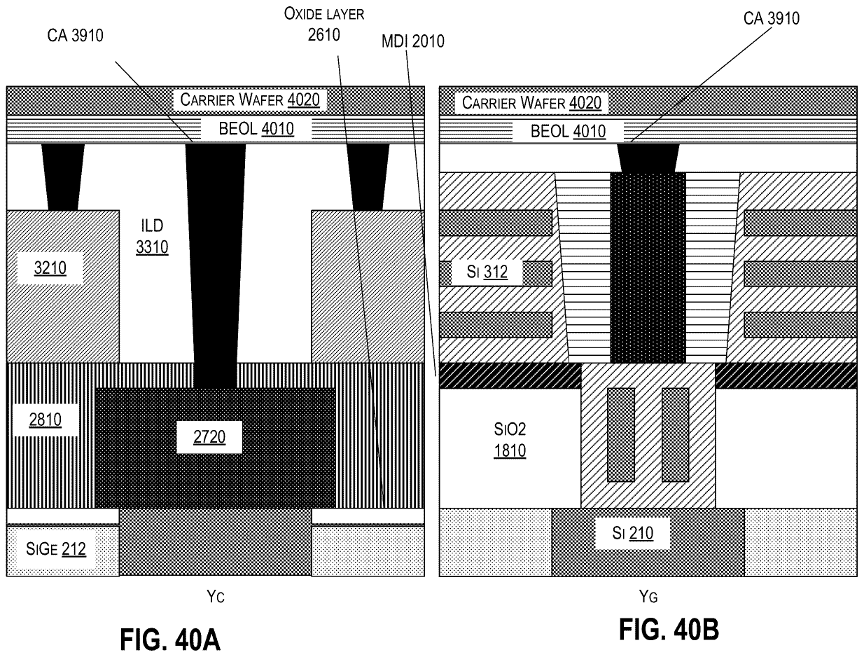

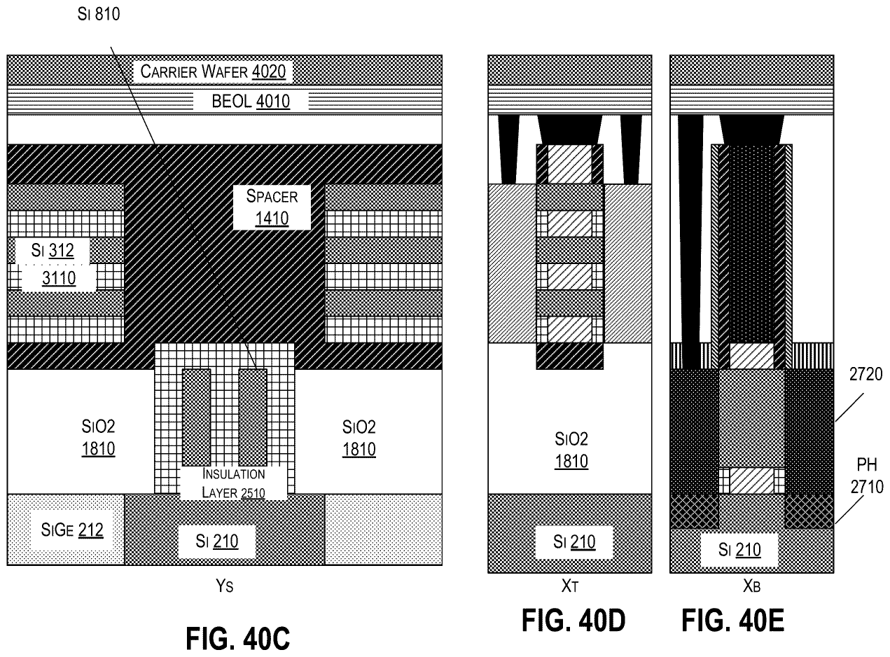

FIGS. 40A-40E illustrate a semiconductor device after the partial removal of the substrate, in accordance with some embodiments.

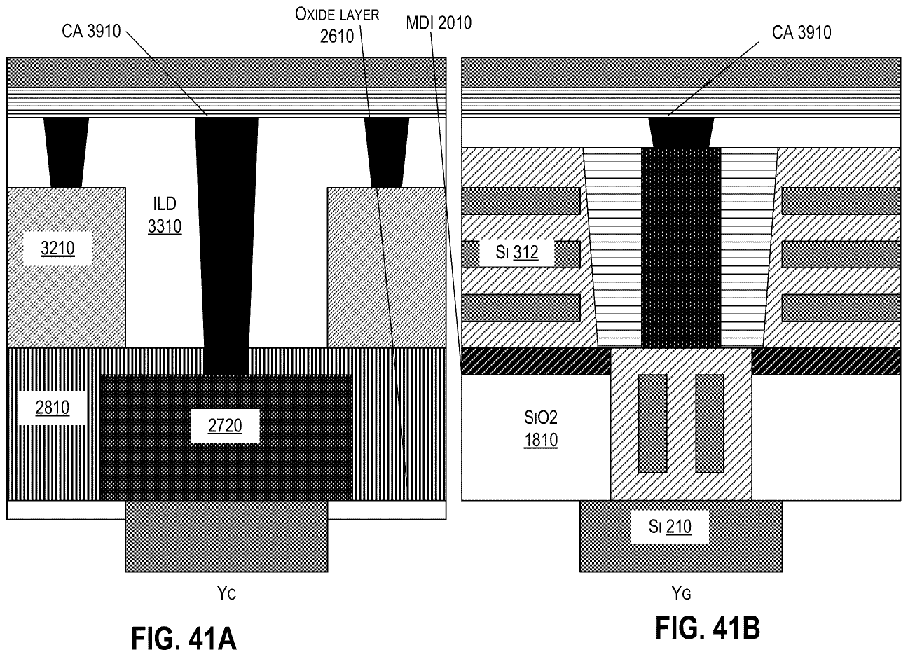

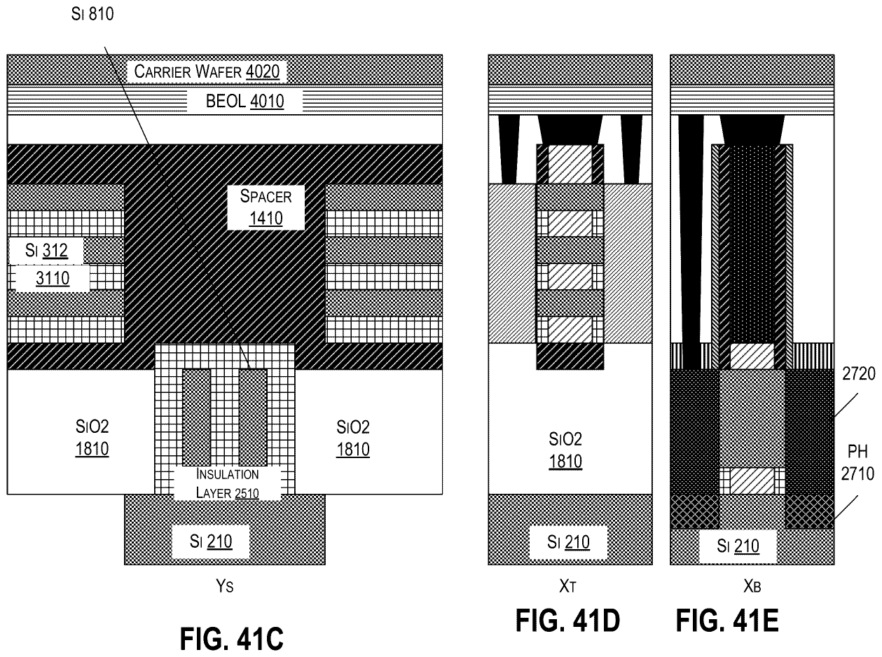

FIGS. 41A-41E illustrate a semiconductor device after the removal of the SiGe, in accordance with some embodiments. In some embodiments, the SiGe is removed.

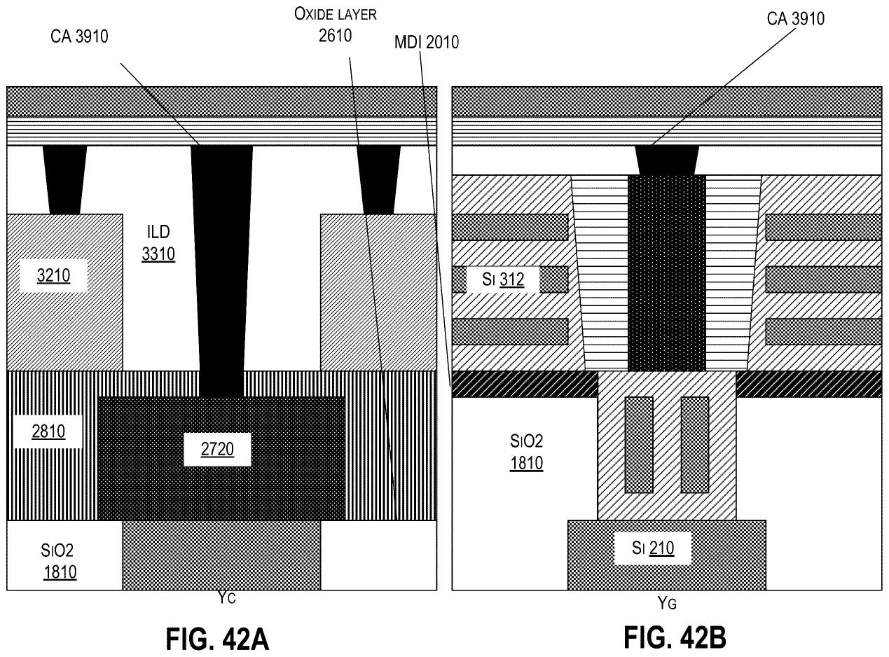

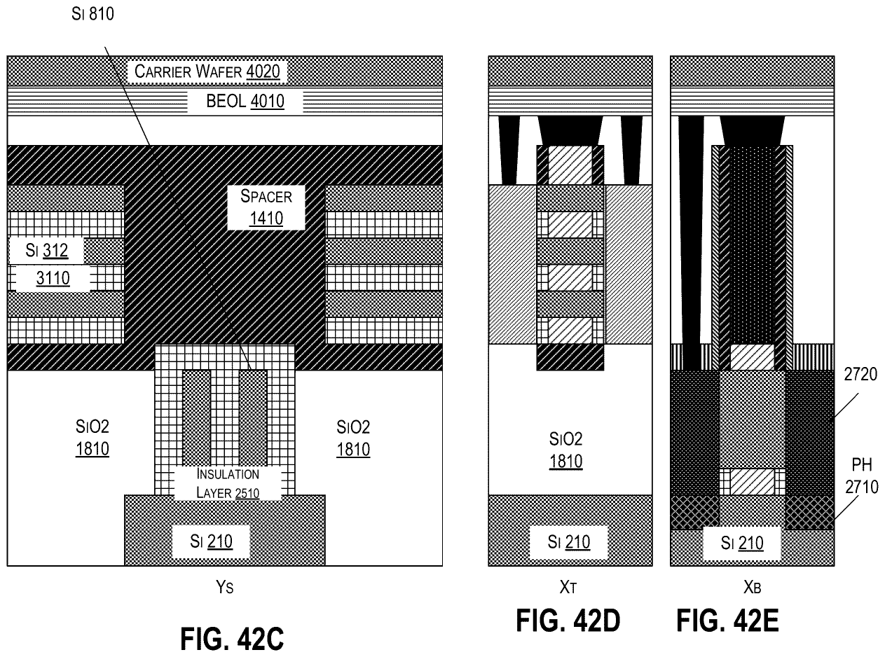

FIGS. 42A-42E illustrate a semiconductor device after the formation of the SiO2, in accordance with some embodiments. In some embodiments, an SiO2 is formed to replace the removed SiGe.

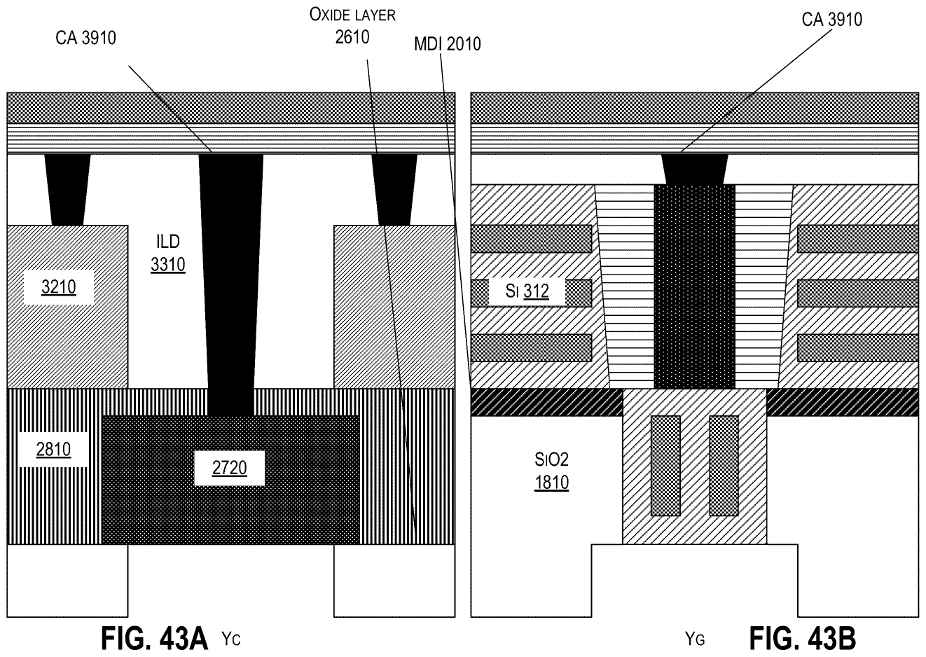

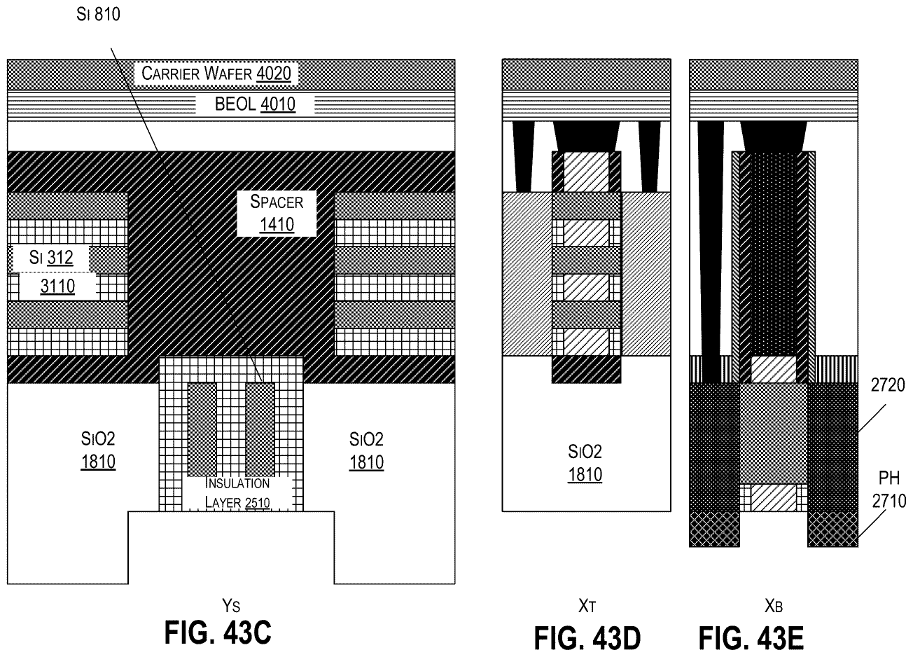

FIGS. 43A-43E illustrate a semiconductor device after the removal of the substrate, in accordance with some embodiments. In some embodiments, the substrate is removed.

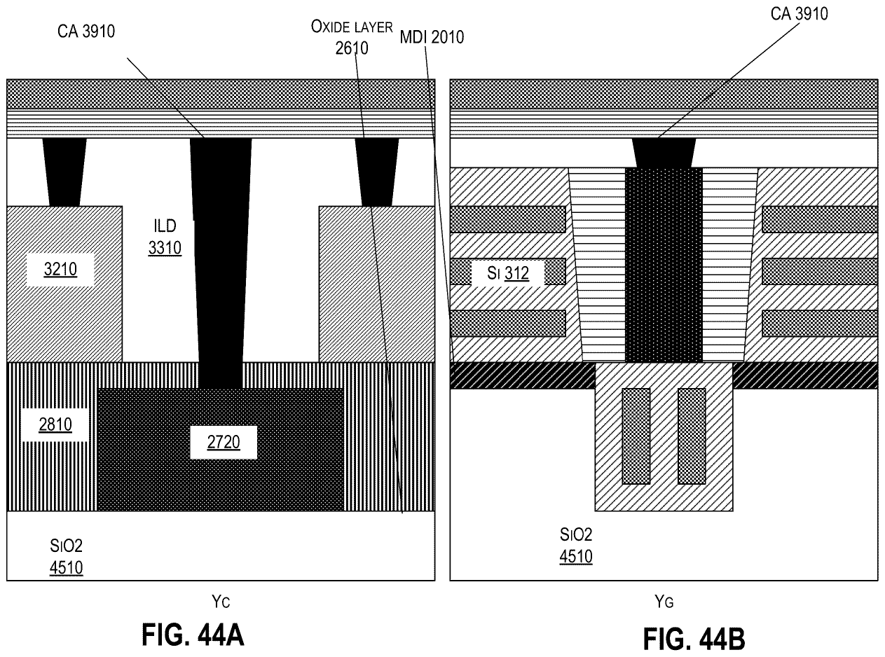

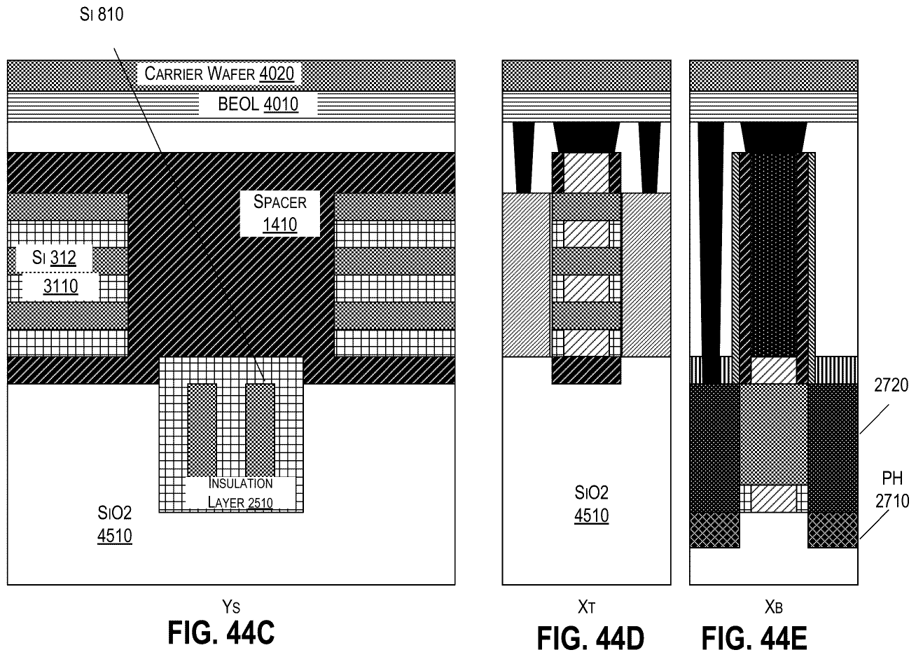

FIGS. 44A-44E illustrate a semiconductor device after the formation of SiO2, in accordance with some embodiments. In some embodiments, a SiO2 is formed to replace the substrate. As a result, a SiO2 4510 covers the backside of the semiconductor device.

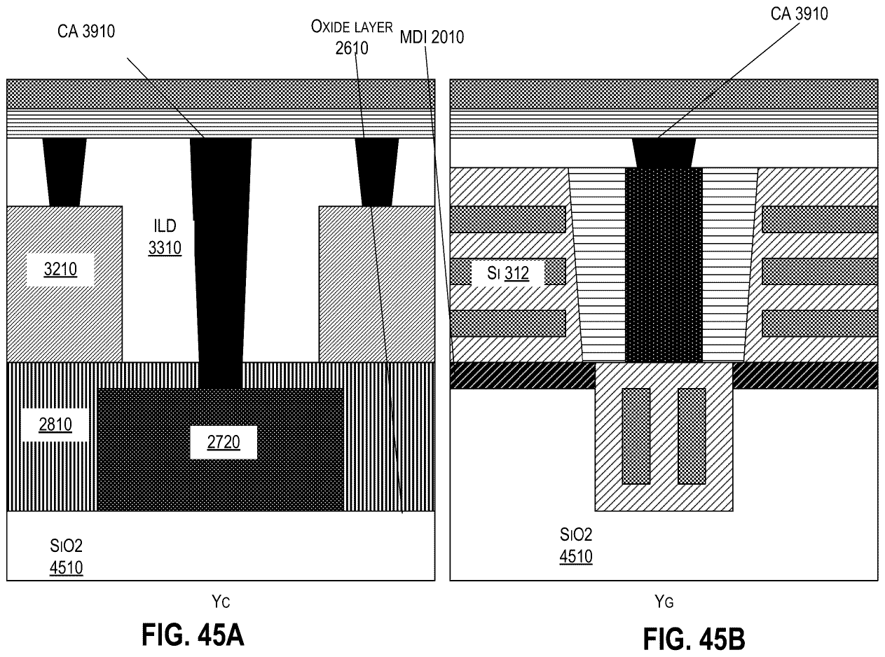

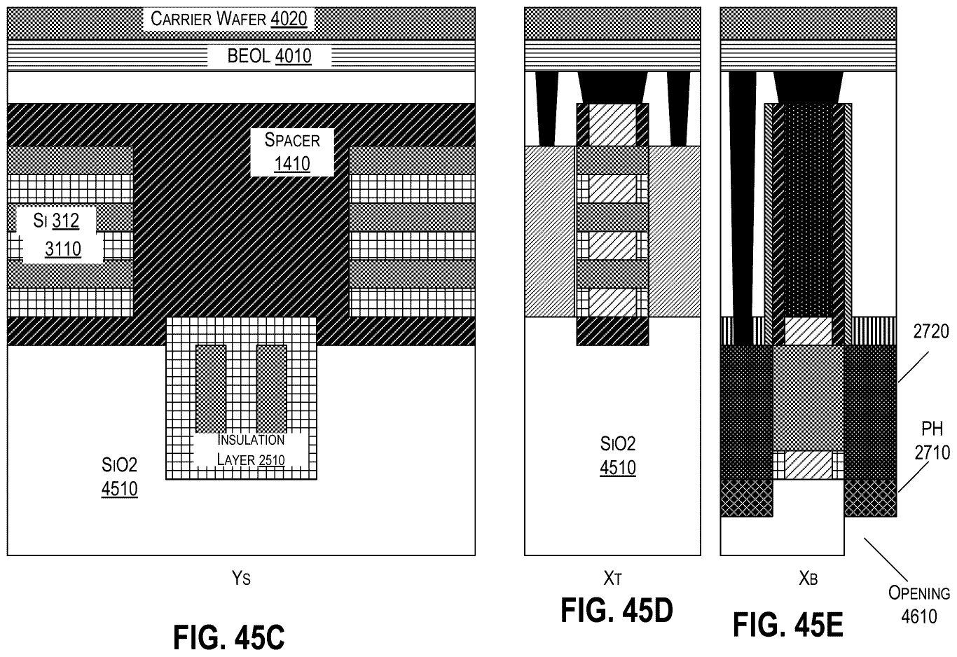

FIGS. 45A-45E illustrate a semiconductor device after the patterning of the backside contact, in accordance with some embodiments. In some embodiments, an opening 4610 is formed to be used to form the backside contact.

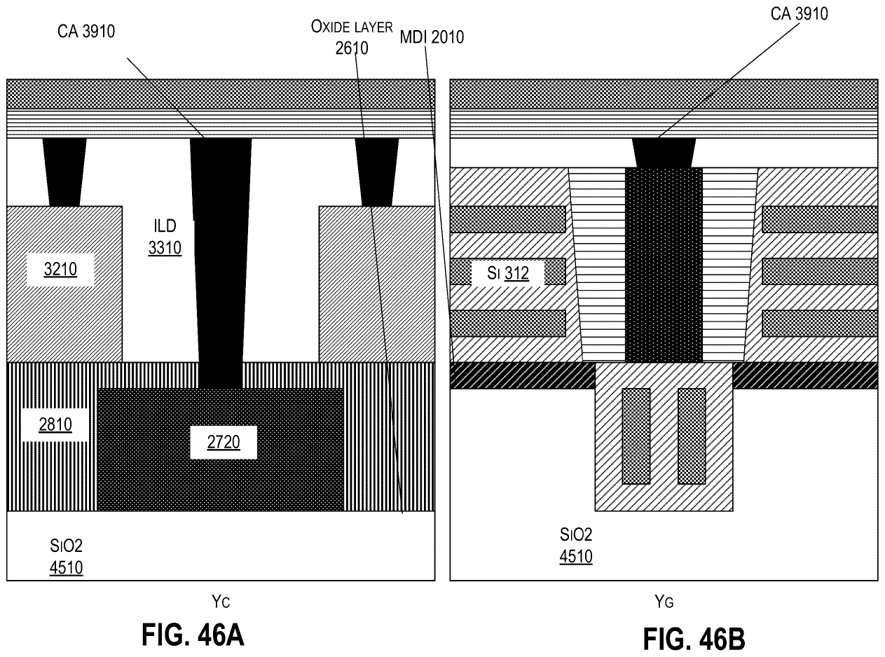

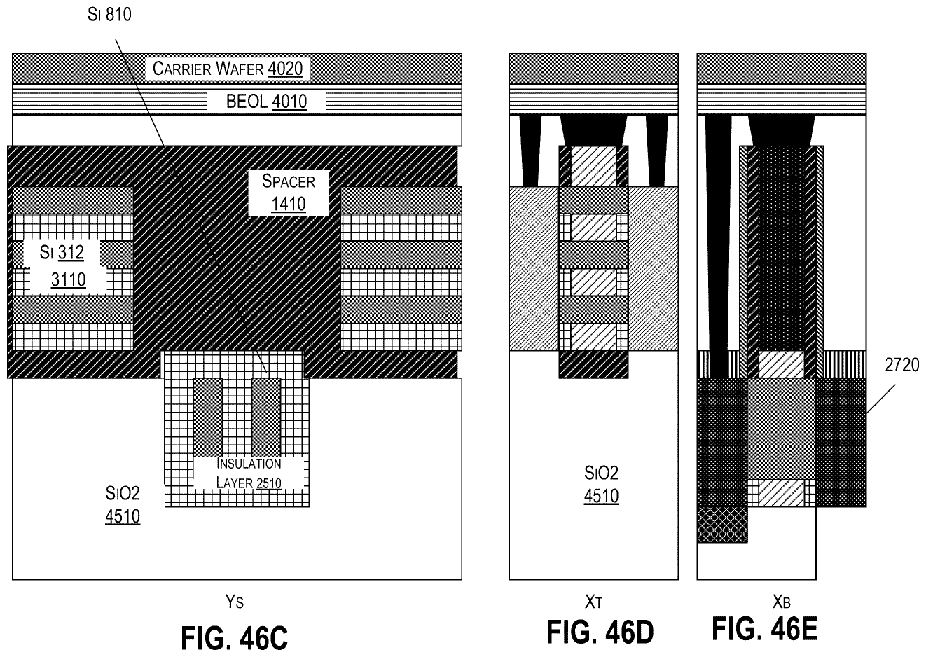

FIGS. 46A-46E illustrate a semiconductor device after the removal of the placeholder, in accordance with some embodiments. In some embodiments, a PH 2710 is removed.

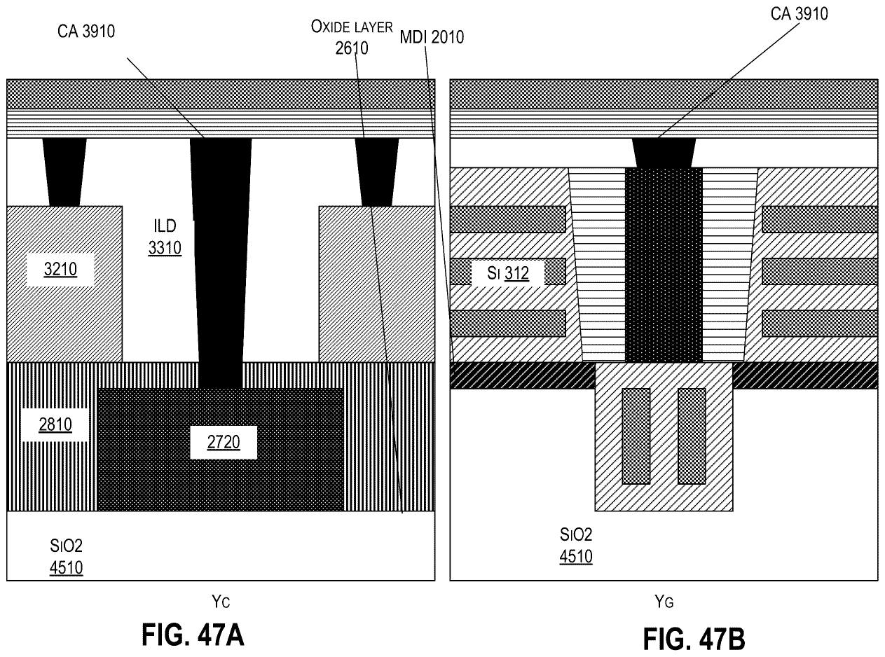

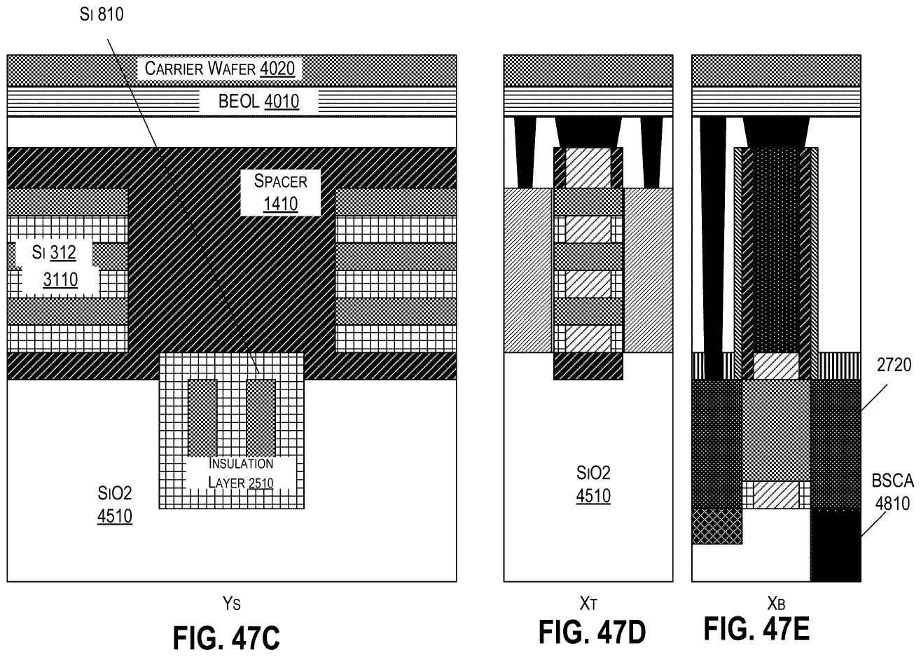

FIGS. 47A-47E illustrate a semiconductor device after the formation of the backside contact, in accordance with some embodiments. In some embodiments, a backside contact, BSCA 4810, is formed to connect a source/drain region to the backside of the semiconductor device.

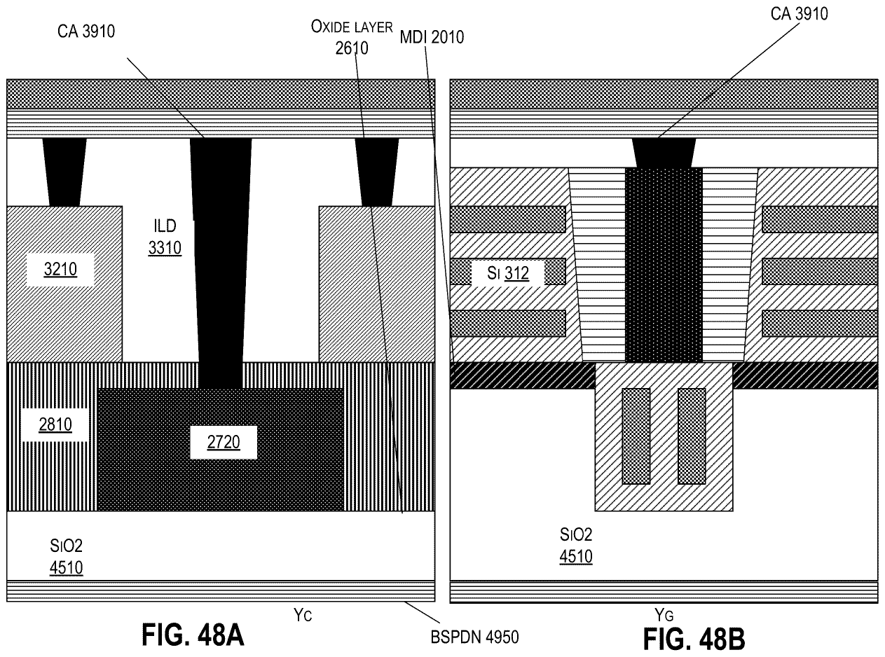

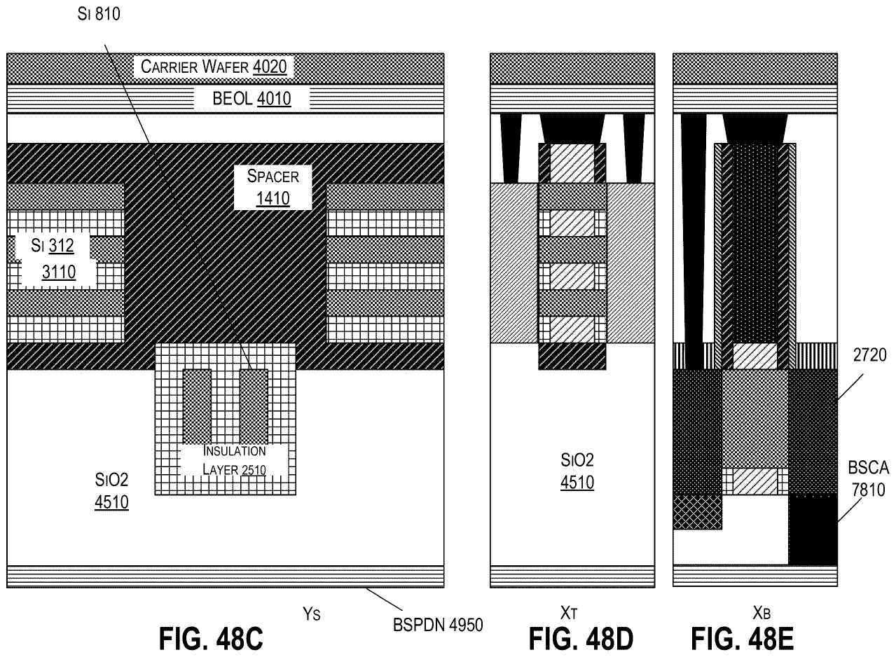

FIGS. 48A-48E illustrate a semiconductor device after the formation of the backside power delivery network, in accordance with some embodiments. In some embodiment, a backside power delivery network, BSPDN 4950, is formed on the backside of the semiconductor device.

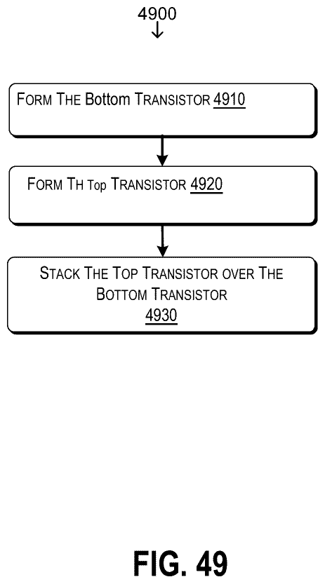

FIG. 49 illustrates a block diagram of a method 4900 for forming the semiconductor device, in accordance with some embodiments.

As shown by block 4910, the bottom transistor is formed. The bottom transistor can include horizontally oriented nanosheet gates;

As shown by block 4920, the top transistor is formed. The top transistor can include vertically oriented nanosheet gates.

As shown by block 4930, the top transistor is stacked over the bottom transistor.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a top transistor stacked over a bottom transistor, wherein:
the top transistor comprises horizontally oriented nanosheet gates; and
the bottom transistor comprises vertically oriented nanosheet gates, wherein the top transistor and bottom transistor staggered.

2. The semiconductor device of claim 1, wherein the top transistor and the bottom transistor further comprise staggered source/drain regions.

3. The semiconductor device of claim 2, wherein the staggered source/drain regions are separated by an insulator.

4. The semiconductor device of claim 1, wherein the horizontally oriented nanosheet gates and the vertically oriented nanosheet gates are isolated by an interlayer dielectric.

5. The semiconductor device of claim 1, further comprising an insulator over source/drain regions of the bottom transistor.

6. The semiconductor device of claim 1, wherein the vertically oriented nanosheet gates are encapsulated by an insulator.

7. The semiconductor device of claim 1, wherein the horizontally oriented nanosheet gates are separated by an insulator.

8. The semiconductor device of claim 1, wherein the horizontally oriented nanosheet gates and the vertically oriented nanosheet gates include silicon.

9. A method for fabrication of a semiconductor device, the method comprising:
forming a top transistor comprising horizontally oriented nanosheet gates;
forming a bottom transistor comprising vertically oriented nanosheet gates; and
stacking the top transistor over the bottom transistor, wherein the top transistor and bottom transistor are formed staggered.

10. The method of claim 9, further comprising forming staggered source/drain regions in the top transistor and the bottom transistor.

11. The method of claim 10, further comprising isolating the staggered source/drain regions by an insulator.

12. The method of claim 9, further comprising isolating the horizontally oriented nanosheet gates and the vertically oriented nanosheet gates by an interlayer dielectric.

13. The method of claim 9, further comprising forming an insulator over source/drain regions of the bottom transistor.

14. The method of claim 9, further comprising encapsulating the vertically oriented nanosheet gates by an insulator.

15. The method of claim 9, further comprising isolating the horizontally oriented nanosheet gates by an insulator.

16. The method of claim 9, wherein the horizontally oriented nanosheet gates and the vertically oriented nanosheet gates include silicon.

17. A semiconductor device, comprising:
a top transistor stacked over a bottom transistor, wherein the top transistor and the bottom transistor further comprises staggered source/drain regions.

18. The semiconductor device of claim 17, wherein:
the top transistor comprises horizontally oriented nanosheet gates; and
the bottom transistor comprises vertically oriented nanosheet gates.

19. The semiconductor device of claim 17, wherein the staggered source/drain regions are separated by an insulator.

20. The semiconductor device of claim 18, wherein the horizontally oriented nanosheet gates and the vertically oriented nanosheet gates are isolated by an interlayer dielectric.
